(19) United States
(12) Patent Application Publication
(10) Pub. No.: US 2026/0271390 A1
(43) Pub. Date: Sep. 10, 2026

(54) SEMICONDUCTOR STRUCTURE INCLUDING GATE ELECTRODE DOPED WITH STRESSOR ELEMENT AND METHOD FOR MANUFACTURING THE SAME

(71) Applicant: TAIWAN SEMICONDUCTOR MANUFACTURING COMPANY, LTD., Hsinchu (TW)

(72) Inventors: Chun-Fu LU, Hsinchu (TW); Wei-Tung LIN, Hsinchu (TW); Shih-Hao LAI, Hsinchu (TW); Lung-Kun CHU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/074,008

(22) Filed: Mar. 7, 2025

(51) Int. Cl. H10D 84/85; H10D 30/00; H10D 30/01; H10D 30/69; H10D 62/10; H10D 64/66; H10D 84/01

(52) U.S. Cl. CPC H10D 84/851; H10D 30/0191; H10D 30/502; H10D 30/794; H10D 62/121; H10D 64/666; H10D 64/667; H10D 64/671; H10D 84/0177

(57) ABSTRACT

A semiconductor structure includes: an active region disposed over a substrate; and a gate structure extending over a top portion of the active region, the gate structure having a curved top surface, the gate structure including a gate dielectric layer and a gate electrode over the gate dielectric layer, the gate electrode including a seam, the gate electrode including a work function layer, the work function layer including a work function material and a stressor element doped in the work function material, the stressor element including a metal element that is different from a metal element in the work function material, the stressor element being present in an amount sufficient to permit the work function layer to apply a stress on the top portion of the active region.

### BACKGROUND

At present, integrated circuits (ICs) are widely used in consumer electronics products (such as mobile phones), high performance computing applications, and automotive electronic products. Scaling down the size of semiconductor devices leads to a decrease in chip size, which is in accordance to Moore's Law. In order to manufacture electronics products with relatively lower power consumption, longer service lifetime, higher computing speed, and so on, many approaches are being continuously developed for optimizing each of the transistors in the IC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 27C illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

The present disclosure is directed to a semiconductor structure which includes metal-oxide-semiconductor (MOS) devices formed on different regions, and a method for manufacturing the same. The MOS devices are formed to have different electrical properties by varying materials of, for example, work function layers, and/or dipole layers of a gate structure of the MOS devices. For example, each of the work function layers of the gate structure is doped with a suitable stressor element, and thus, each of the work function layers is configured as a stress film, so as to generate a stress to be applied on channels of a corresponding one of the MOS devices. Through the selection of the stressor element which will be described in the present disclosure, the stress applied on the channels may be a tensile stress or a compressive stress. The mobility of carriers (e.g., electrons or holes) within the channels may be increased due to the stress applied on the channels, thereby improving the device performance of the corresponding one of the MOS devices.

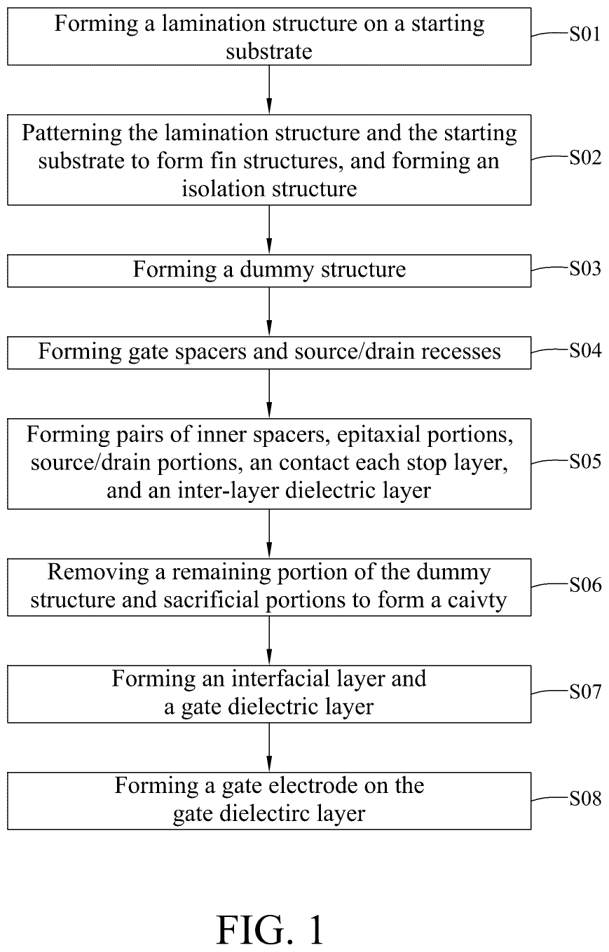

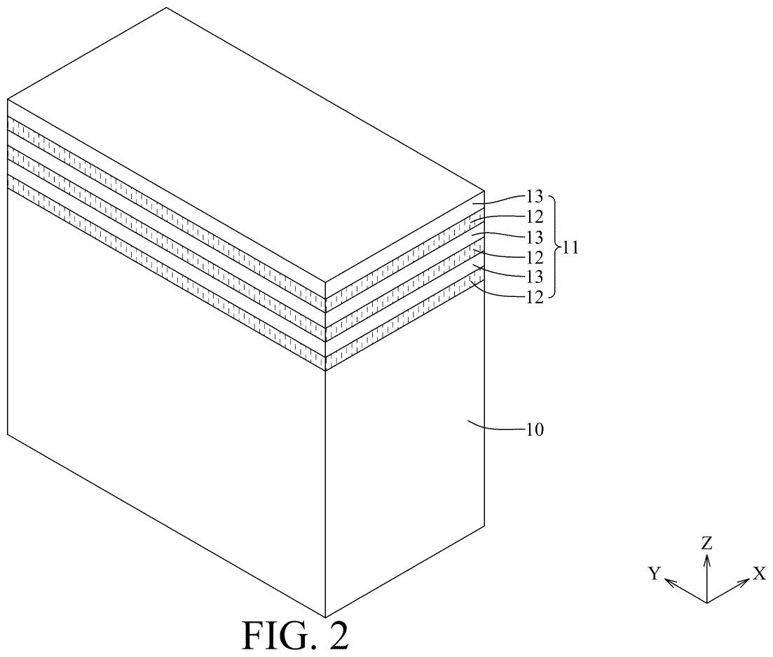

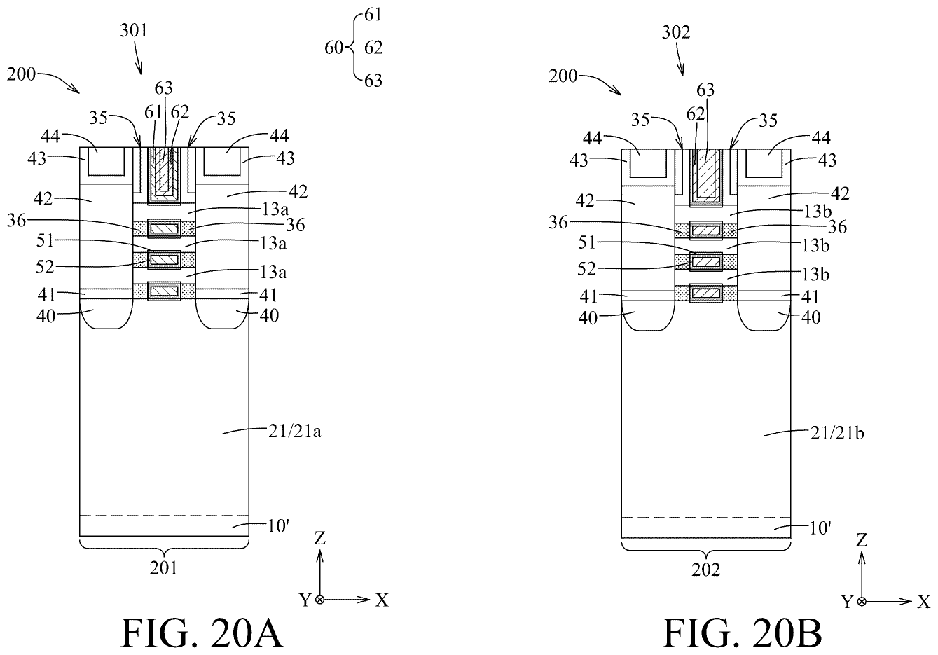

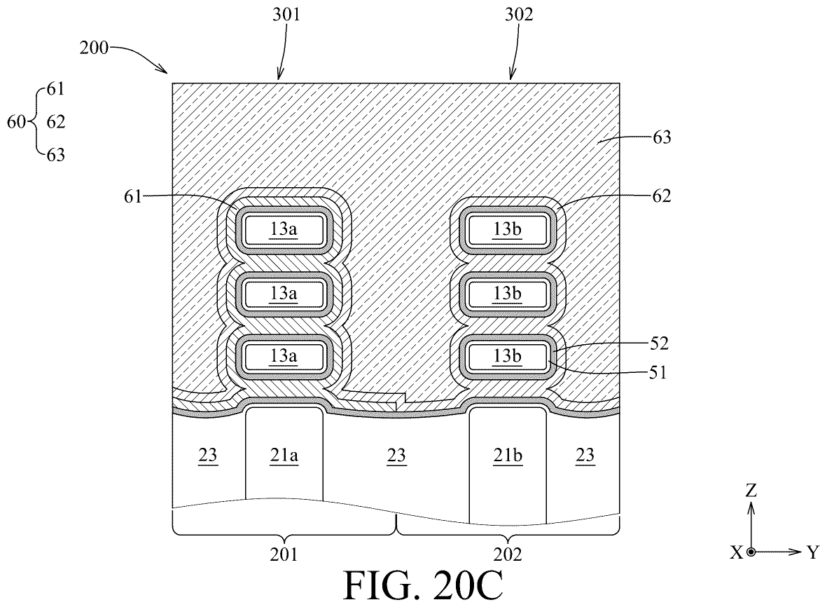

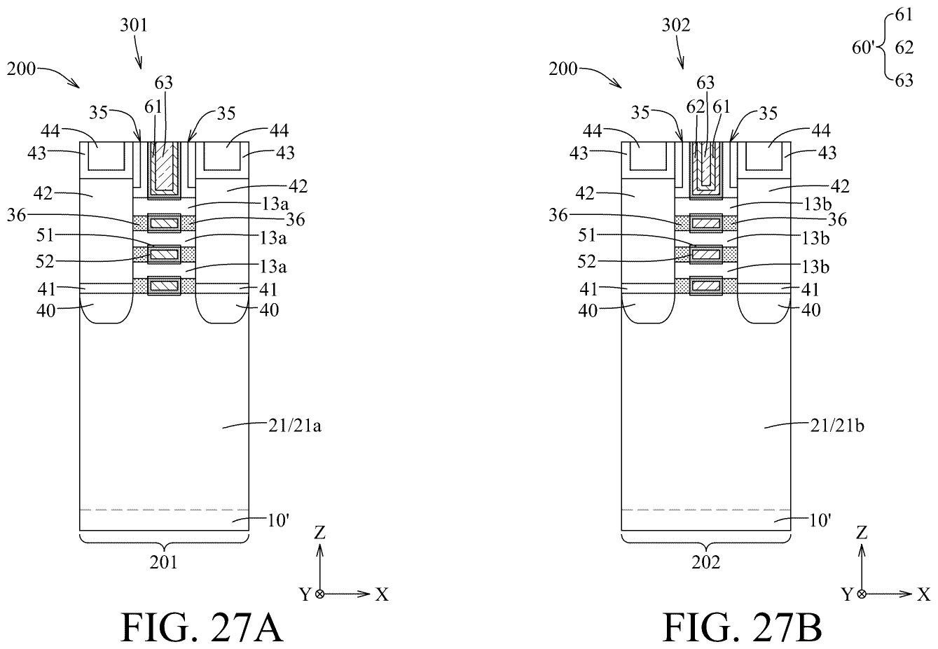

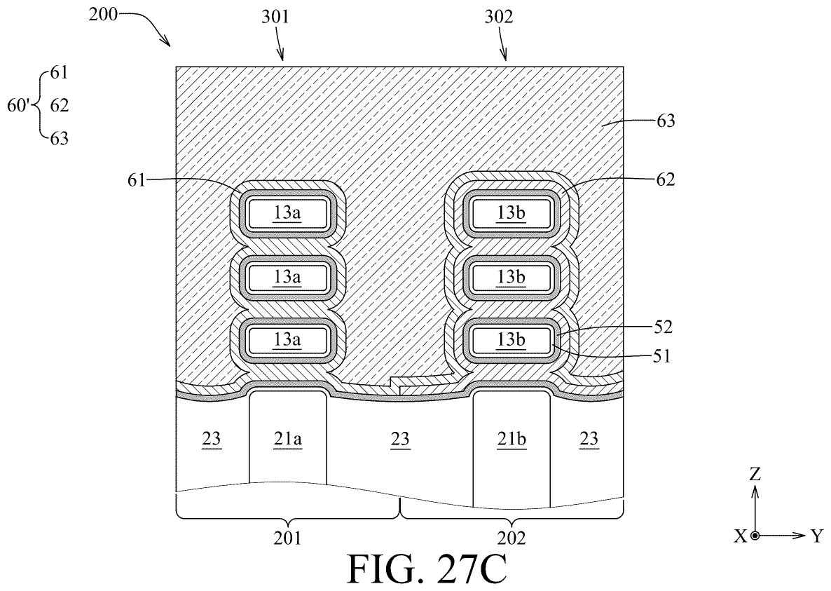

FIG. 1 is a flow diagram illustrating a method 100 for manufacturing a semiconductor structure (for example, but not limited to, a semiconductor structure 200 shown in FIGS. 20A to 20C, or the semiconductor structure 200 shown in FIGS. 27A to 27C) in accordance with some embodiments. The method 100 may include steps S01 to S08. FIGS. 2 to 27C illustrate schematic views of intermediate stages of the method 100 in accordance with some embodiments. Some repeating structures are omitted in FIGS. 2 to 27C for the sake of brevity. Additional steps can be provided before, after or during the method 100, and some steps in the method 100 may be modified, replaced, or eliminated without departure from the spirit and scope of the present disclosure.

As shown in FIGS. 20A to 20C, the semiconductor structure 200 includes a first device 301 formed on a first region 201 and a second device 302 formed on a second region 202. In some embodiments, as shown in FIG. 20C, the semiconductor structure 200 may be configured to be a gate-all-around (GAA) structure, in which four side surfaces of each channel of each of the first device 301 and the second device 302 are covered by a gate structure 60. In some other embodiments not shown herein, the semiconductor structure may be configured as a forksheet structure which is an advanced variation of the GAA structure in advanced technology nodes of semiconductor fabrication. In the forksheet structure, a dielectric wall is formed on an isolation structure and is located between each channel of the first device 301 and each channel of the second device 302 for electrical isolation, so that a spacing (i.e., OD-to-OD spacing) between the first device 301 and the second device 302 can be effectively reduced. Alternatively, the semiconductor structure may be configured as a complementary field-effect transistor (CFET) structure, in which the first device 301 and the second device 302 are stacked vertically on top of each other over a substrate.

FIG. 2 is a schematic perspective view illustrating a starting substrate 10 and a lamination structure 11 formed on the starting substrate 10 in accordance with some embodiments.

In some embodiments, the starting substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the starting substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the starting substrate 10 may be formed with an n-type well having an n-type conductivity and a p-type well having a p-type conductivity. Each of the n-type well and the p-type well may be formed by introducing an n-type impurity or a p-type impurity into the starting substrate 10 by an implantation process. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the starting substrate 10 may be configured as a semiconductor-on-insulator substrate. Other suitable materials and configurations for the starting substrate 10 are within the contemplated scope of the present disclosure.

The lamination structure 11 may include sacrificial layers 12 and channel layers 13 disposed to alternate with the sacrificial layers 12 in a Z direction.

Each of the sacrificial layers 12 is made of a first semiconductor material, and each of the channel layers 13 is made of a second semiconductor material that is different from the first semiconductor material, so that the sacrificial layers 12 may be selectively removed in a subsequent step while leaving the channel layers 13 substantially intact due to different etching rates. Possible semiconductor materials suitable for the sacrificial layers 12 and the channel layers 13 are similar to those for the starting substrate 10, and thus details thereof are omitted for the sake of brevity. In some embodiments, the sacrificial layers 12 are made of silicon germanium, and the channel layers 13 are made of silicon. Other materials suitable for the sacrificial layers 12 and the channel layers 13 are within the contemplated scope of the present disclosure. In some embodiments, each of the sacrificial layers 12 has a thickness ranging from about 4 nm to about 14 nm. In some embodiments, each of the channel layers 13 has a thickness ranging from about 3 nm to about 9 nm, or ranging from about 5 nm to about 8 nm.

In some embodiments, the lamination structure 11 is formed by chemical vapor deposition (CVD), atomic layer deposition (ALD), an epitaxial growth process (such as molecular-beam epitaxy (MBE), selective area epitaxy (SAE), etc.), or other suitable deposition techniques. The structure shown in FIG. 2 is obtained after step S01 of the method 100 as shown in FIG. 1.

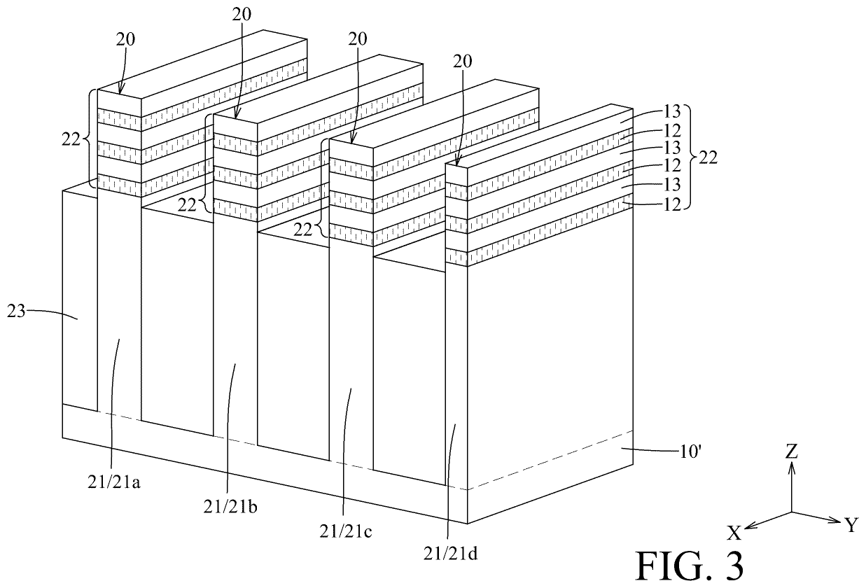

Referring to FIG. 3, the lamination structure 11 and the starting substrate 10 is patterned using a photolithography process followed by an etching process, so as to form a trench (not shown) extending into the starting substrate 10. The lamination structure 11 is formed into film stacks 22, and the starting substrate 10 is formed into protrusions 21 (including the protrusions 21a, 21b, 21c, 21d) on a substrate 10′. The film stacks 22 are respectively disposed on the protrusions 21. The protrusions 21 and the film stacks 22 collectively constitute fin structures 20, each of which includes one of the protrusions 21 and a respective one of the film stacks 22. In some embodiments, the one of the protrusions 21 may be referred to as a base portion (or a lower portion) of an active region, and the channel layers 12 in the respective one of the film stacks 22 may be collectively referred to as a top portion (or an upper portion) of the active region.

The fin structures 20 extend lengthwise along an X direction transverse to the Z direction, and two adjacent ones of the fin structures 20 are spaced apart from each other in a Y direction transverse to each of the X and Z directions. The number of the fin structures 20 may vary according to practical applications and is not limited to the number exemplarily shown in FIG. 3. In some embodiments, the X, Y and Z directions are perpendicular to each other.

Next, still referring to FIG. 3, an isolation structure 23 is formed in the trench. The isolation structure 23 is disposed over the substrate 10′ around the protrusions 21, so that two adjacent ones of the protrusions 21 are separated by the isolation structure 23. An upper part of each of the protrusions 21 is exposed from the isolation structure 23. In some embodiments, the isolation structure 23 may be a shallow trench isolation (STI), a deep trench isolation (DTI), or other suitable structures. In some embodiments, the isolation structure 23 may include silicon oxide, silicon nitride, silicon oxynitride, silicon oxide formed from tetraethoxysilane (TEOS), other low-k dielectric materials, or combinations thereof. Other insulating materials suitable for the isolation structure 23 are within the contemplated scope of the present disclosure.

In some embodiments, formation of the isolation structure 23 may include (i) forming an isolation layer (not shown) over the substrate 10′ and the fin structures 20 to fill the trench, (ii) performing a planarization process (for example, but not limited to, chemical mechanical polishing (CMP)) on the isolation layer to form an isolation region (not shown), and (iii) recessing the isolation region until the upper part of each of the protrusions 21 is exposed. The structure shown in FIG. 3 is obtained after step S02 of the method 100 as shown in FIG. 1.

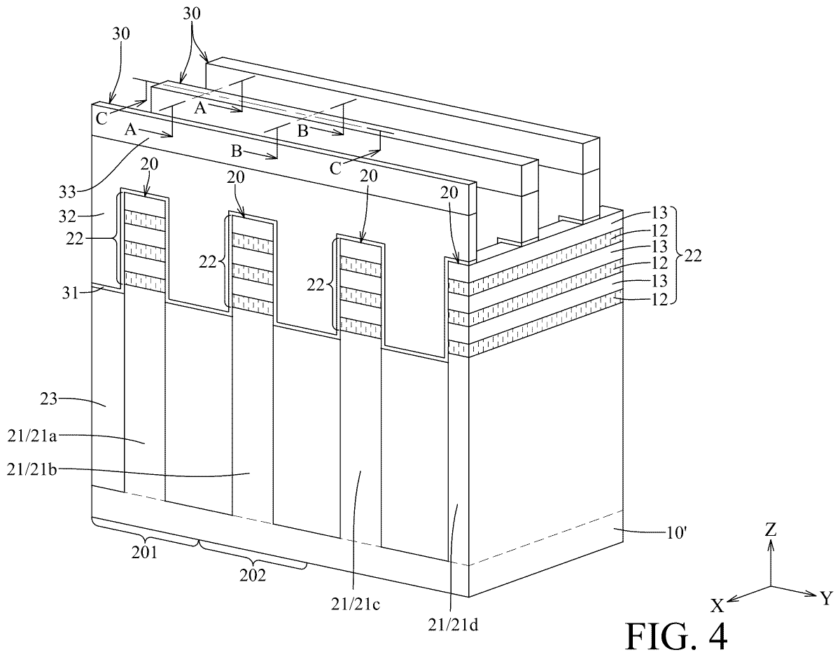

Referring to FIG. 4, dummy structures 30 are formed. Each of the dummy structures 30 extends lengthwise along the Y direction over the fin structures 20 and the isolation structure 23. The dummy structures 30 are spaced apart from each other in the X direction.

Each of the dummy structures 30 includes a dummy dielectric 31, a dummy gate 32, and a hard mask 33. The dummy dielectric 31 is disposed over the fin structures 20 and the isolation structures 23. The dummy gate 32 and the hard mask 33 are sequentially formed on the dummy dielectric 31. In some embodiments, the dummy dielectric 31 may include silicon oxide, silicon nitride, silicon oxynitride, high dielectric constant (k) materials, other suitable dielectric materials, or combinations thereof. In some embodiments, the dummy gate 32 may include polycrystalline silicon, single crystalline silicon, amorphous silicon, or combinations thereof. In some embodiments, the hard mask 33 may include silicon nitride, silicon oxide, silicon oxynitride, or combinations thereof. Other materials suitable for the dummy structures 30 are within the contemplated scope of the present disclosure. In some embodiments, formation of the dummy structures 30 may include (i) sequentially forming a first dummy layer (not shown) for forming the dummy dielectric 31 and a second dummy layer (not shown) for forming the dummy gate 32 over the fin structures 20 and the isolation structure 23 by CVD, ALD, physical vapor deposition (PVD), or other suitable deposition techniques, (ii) performing a planarization process (e.g., CMP) to obtain a planar upper surface of the second dummy layer, (iii) forming a third dummy layer (not shown) for forming the hard mask 33 on the planarized second dummy layer, and (iv) patterning the first dummy layer, the planarized second dummy layer, and the third dummy layer using a photolithography process followed by an etching process, thereby obtaining the dummy structures 30.

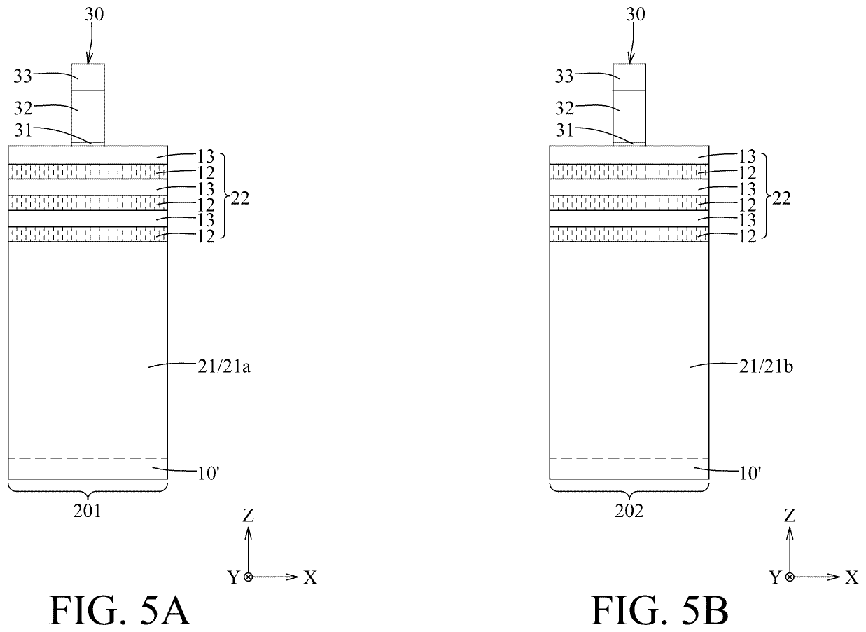

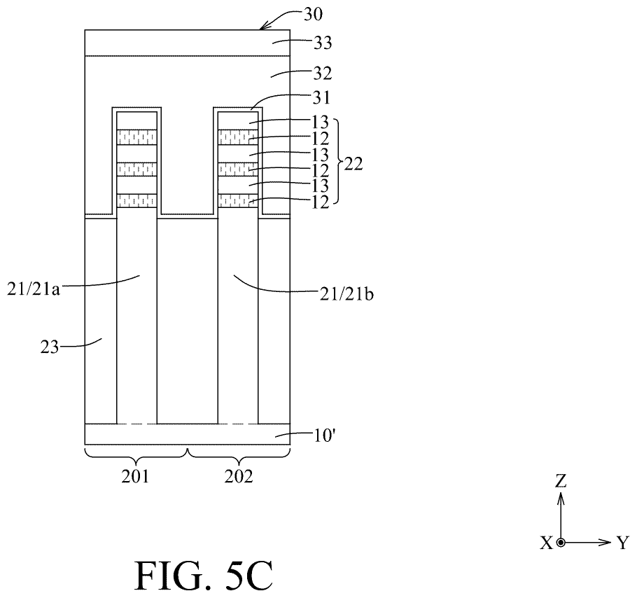

FIGS. 5A and 5B are schematic sectional views respectively taken along line A-A and line B-B of FIG. 4, and may be each referred to as an X-cut view, or a view when viewed along the Y direction. FIG. 5C is a schematic sectional view taken along line C-C of FIG. 4, and may be referred to as a Y-cut view, or a view when viewed along the X direction. For the sake of brevity and clarity, a middle one of the dummy structures 30 and two of the fin structures 20 respectively formed on the first region 201 and the second region 202 shown in FIG. 4 are shown in the following figures and used to illustrate the following steps. The structure shown in FIGS. 5A to 5C is obtained after step S03 of the method 100 as shown in FIG. 1.

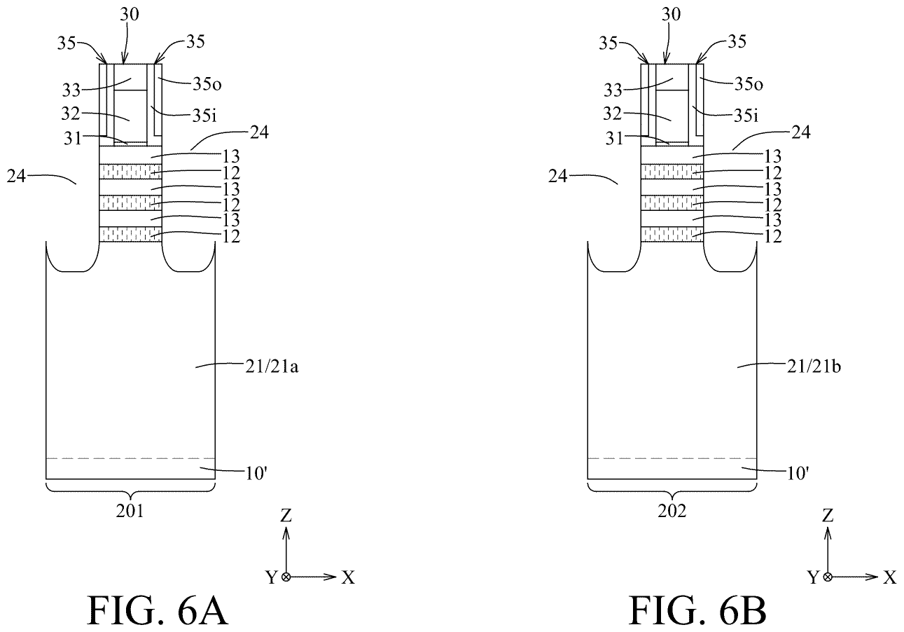

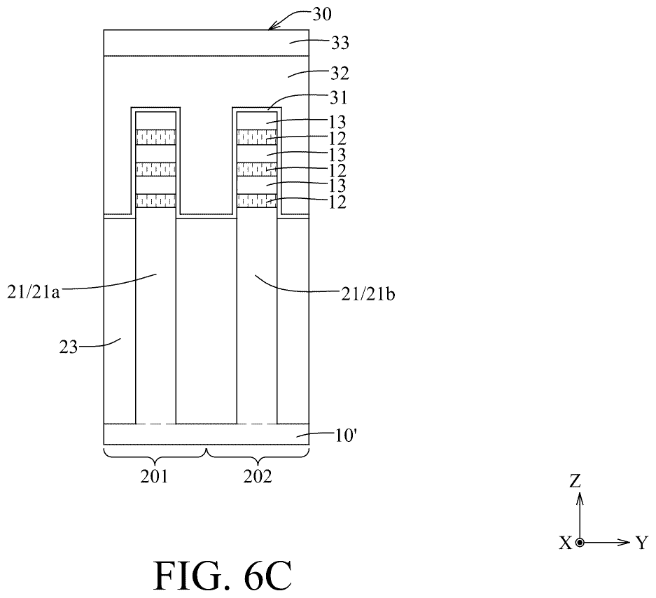

Referring to FIGS. 6A to 6C, two gate spacers 35 are respectively formed at two opposite sides of the dummy structure 30 in the X direction.

In some embodiments, formation of the gate spacers 35 includes: forming a spacer layer (not shown) to cover the dummy structure 30, portions of the fin structures 20 and the isolation structure 23 which are exposed from the dummy structure 30 by CVD, ALD, PVD, or other suitable deposition techniques; and performing an anisotropic etching process on the spacer layer to remove horizontal portions of the spacer layer, while leaving vertical portions of the spacer layer. The vertical portions of the spacer layer remain at two side surfaces of the dummy structure 30 opposite to each other in the X direction, and remain at two side surfaces of each of the fin structures 20. The vertical portions of the spacer layer remaining at the two side surfaces of the dummy structure 30 serve as the gate spacers 35.

In some embodiments, each of the gate spacers 35 includes or is made of, for example, but not limited to, silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. In some embodiments, each of the gate spacers 35 may be configured as a single layer structure or a multi-layered structure. For example, as shown in FIGS. 6A and 6B, each of the gate spacers 35 is formed as a bi-layered structure including an outer sub-layer 35o, and an inner sub-layer 35i which is disposed between the outer sub-layer 35o and the dummy structure 30. The outer sub-layer 35o has a dielectric constant value (k-value) that is greater than a k-value of the inner sub-layer 35i. The k-value of each of the outer and inner sub-layers 35o, 35i may be adjusted by varying the proportions of silicon, oxygen, carbon, nitrogen, and/or other elements (such as hydrogen) in the dielectric material thereof.

Next, still referring to FIGS. 6A to 6C, two source/drain recesses 24 are formed each of the film stacks 22 (see FIGS. 5A and 5B) by an etching process (for example, but not limited to, dry etching, wet etching, or a combination thereof). In some embodiments, each of the source/drain recesses 24 may extend into a corresponding one of the protrusions 21 by a predetermined depth. Accordingly, the channel layers 13 and the sacrificial layers 12 in each of the film stacks 22 are formed into channel portions (still denoted by the reference numeral 13) and sacrificial portions (still denoted by the reference numeral 12). The structure shown in FIGS. 6A to 6C is obtained after step S04 of the method 100 as shown in FIG. 1.

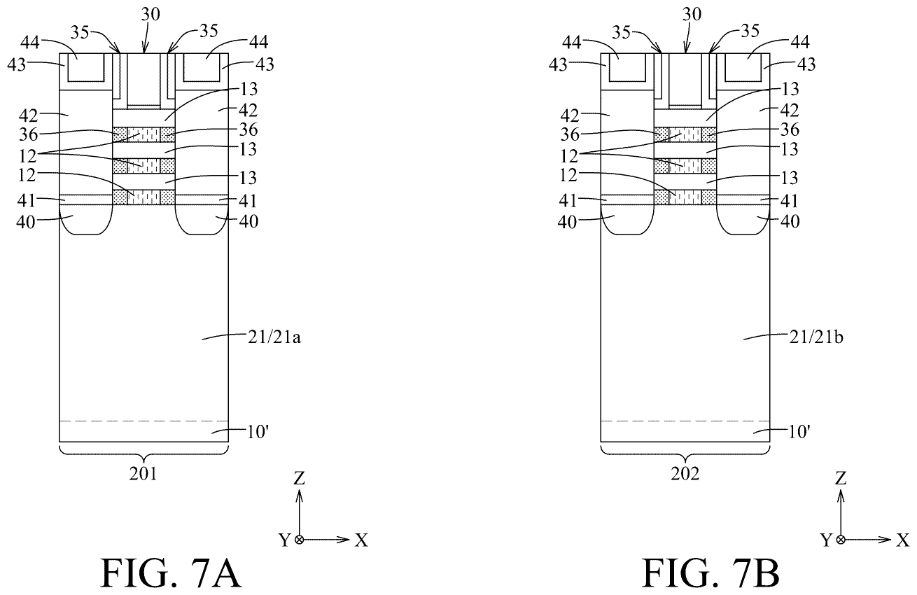

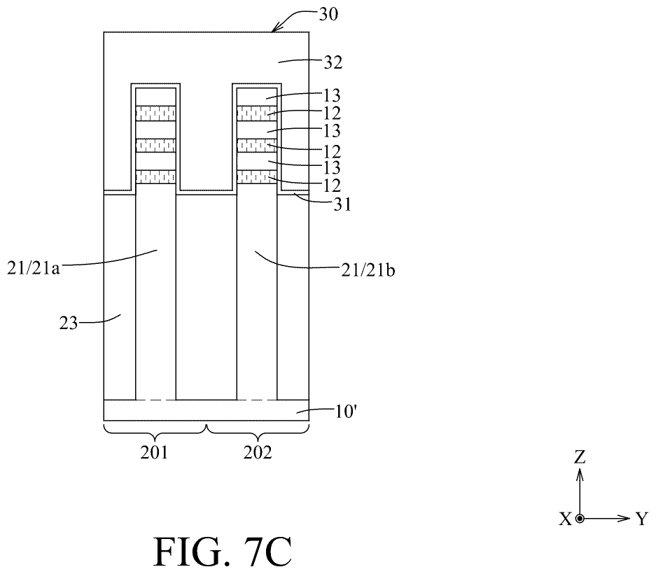

Referring to FIGS. 7A to 7C, the sacrificial portions 12 are trimmed by a selective etching process to have a reduced width in the X direction, while leaving the channel portions 13 substantially intact. Then, pairs of inner spacers 36 are formed by suitable deposition and etching techniques. The inner spacers 36 in each pair are respectively formed at two opposite sides of a respective one of the sacrificial portions 12 in the X direction. In some embodiments, the inner spacers 36 may include silicon oxide, silicon oxycarbide, silicon oxynitride, silicon oxycarbide, silicon oxycarbonitride, air gap, other suitable low-k dielectric materials, or combinations thereof.

In some embodiments not shown herein, after forming the inner spacers 36, the channel portions 13 may be trimmed by a selective etching process to have a reduced width in the X direction.

Next, sill referring to FIGS. 7A to 7C, epitaxial portions 40 are respectively formed at the bottom of the source/drain recesses 24 (see FIGS. 6A and 6B), and source/drain portions 42 are respectively formed to fill the source/drain recesses 24. Each of the channel portions 13 extends between two corresponding adjacent ones of the source/drain portions 42. In some embodiments, bottom isolations 41 may be further formed to reduce leakage current. Each of the bottom isolations 41 is formed between one of the epitaxial portions 40 and a respective one of the source/drain portions 42.

In some embodiments, each of the epitaxial portions 40 includes a semiconductor material (such as the examples of the semiconductor material for forming the substrate 10). In some embodiments, each of the epitaxial portions 40 is independently made of non-doped silicon, silicon germanium, or boron-doped silicon. In some embodiments, each of the epitaxial portions 40 is formed by an epitaxial growth process (such as molecular-beam epitaxy (MBE), selective area epitaxy (SAE), etc.), or other suitable deposition techniques.

In some embodiments, each of the bottom isolations 41 includes or is made of silicon, silicon oxide, silicon nitride, carbon-doped silicon oxide, silicon oxycarbide, silicon oxynitride, silicon oxycarbon nitride, silicon carbon nitride, or combinations thereof. In some embodiments, formation of the bottom isolations 41 may include CVD, ALD, PVD, or other suitable deposition techniques, followed by an etching process to expose the channel portions 13.

In some embodiments, each of the source/drain portions 42 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 42 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or a boron compound (for example, B, ¹¹B, BF₂), aluminum (Al), gallium (Ga), indium (In), other suitable p-type dopants, or combinations thereof. In some other embodiments, the source/drain portions 42 serving as sources or drains of n-MOSFETs may include or be made of silicon phosphide (SiP), silicon arsenide (SiAs), or a combination thereof, and the source/drain portions 42 serving as sources or drains of p-MOSFETs may include or be made of silicon boron (SiB). In some embodiments, each of the source/drain portions 42 may be configured as a multi-layer structure including sub-layers which have different concentrations of dopants. In some embodiments, the source/drain portions 42 are formed by an epitaxial growth process (such as molecular-beam epitaxy (MBE), selective area epitaxy (SAE), etc.), or other suitable deposition techniques.

Then, a contact etch stop layer (CESL) 43 and an inter-layer dielectric (ILD) layer 44 are sequentially formed on the source/drain portions 42 by CVD, PVD, ALD, or other possible deposition processes, followed by a planarization process (e.g., CMP) to expose the dummy gate 32 of the dummy structure 30.

In some embodiments, the CESL 43 includes or is made of a dielectric material that is different from a dielectric material of the ILD layer 44, so that the CESL 43 may serve as an etch stop point during formation of metal contacts each of which penetrates the ILD layer 44 and the CESL 43 so as to connect to a corresponding one of the source/drain portions 42. In certain embodiments, possible dielectric materials suitable for the CESL 43 include silicon nitride, silicon oxynitride, silicon carbonitride, other suitable dielectric materials, or combinations thereof. In some embodiments, the ILD layer 44 includes or is made of silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof. The structure shown in FIGS. 7A to 7C is obtained after step S05 of the method 100 as shown in FIG. 1.

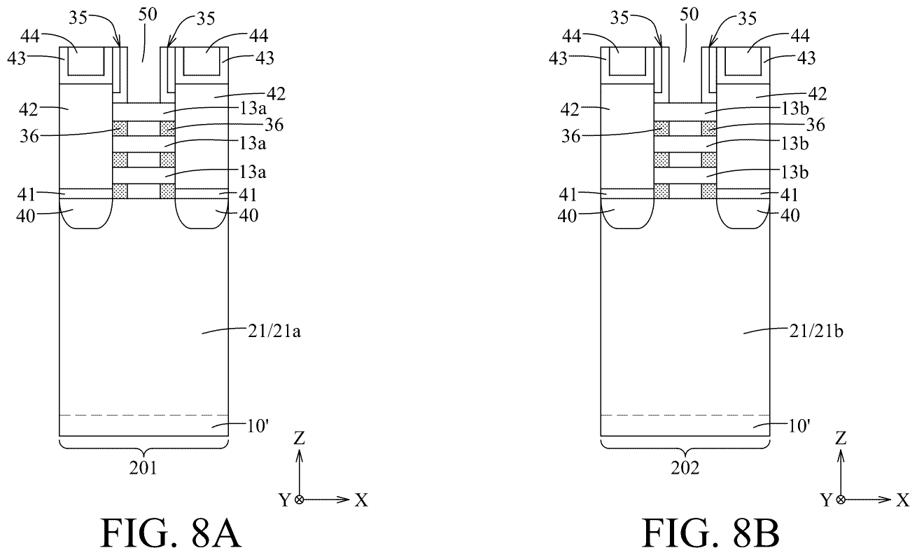

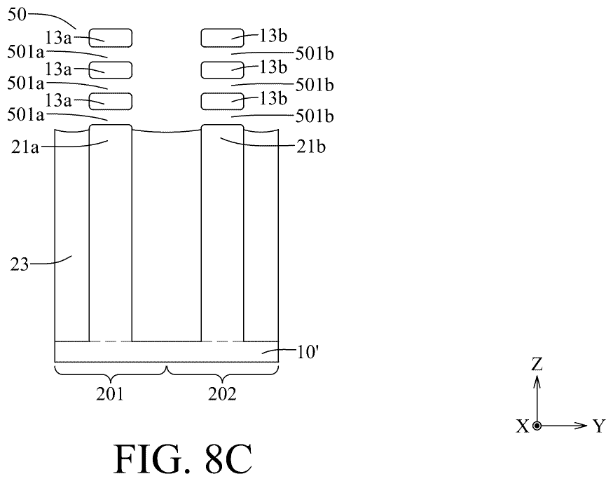

Referring to FIGS. 8A to 8C, the dummy gate 32 and the dummy dielectric 31 of the remaining dummy structure 30, and the sacrificial portions 12 (see FIGS. 7A to 7C) are removed by an etching process (for example, but not limited to, dry etching, wet etching, or a combination thereof), thereby forming a cavity 50.

For the sake of clarity, the channel portions located on the protrusion 21a are denoted by the reference numeral 13a, and the channel portions located on the protrusion 21b are denoted by the reference numeral 13b. The channel portions 13a serve as channels of the first device 301 (see FIGS. 20A and 20C), and the channel portions 13b serve as channels of the second device 302 (see FIGS. 20B and 20C). In some embodiments, the first device 301 may be configured as an n-MOSFET, and the second device 302 may be configured as a p-MOSFET. Hereinafter, for the sake of clarity, the first device 301 is referred to as an NMOS device, and the second device 302 is referred to as a PMOS device.

As shown in FIG. 8C, spaces 501a, 501b are present due to the absence of the sacrificial portions 12 (see FIG. 7C). The spaces 501a are respectively located beneath the channel portions 13a, and the spaces 501b are respectively located beneath the channel portions 13b. The structure shown in FIGS. 8A to 8C is obtained after step S06 of the method 100 as shown in FIG. 1.

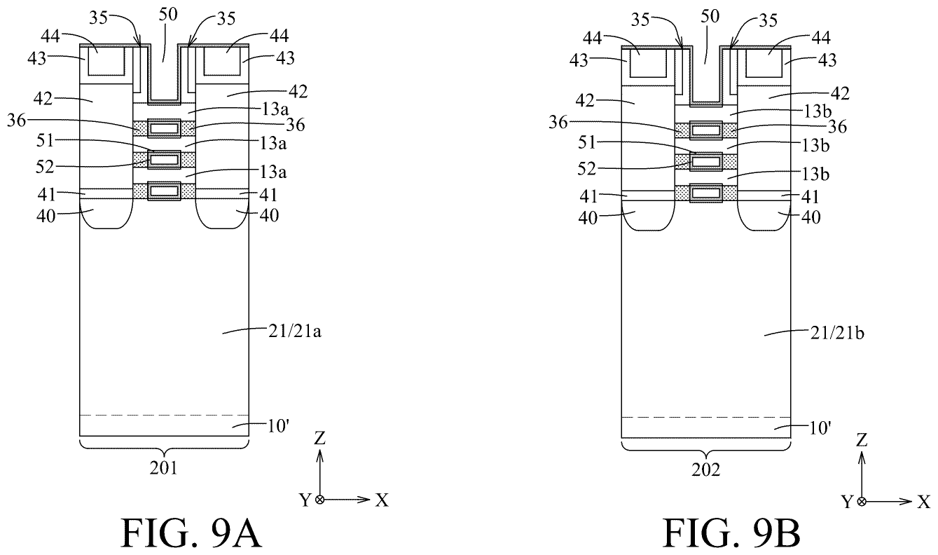

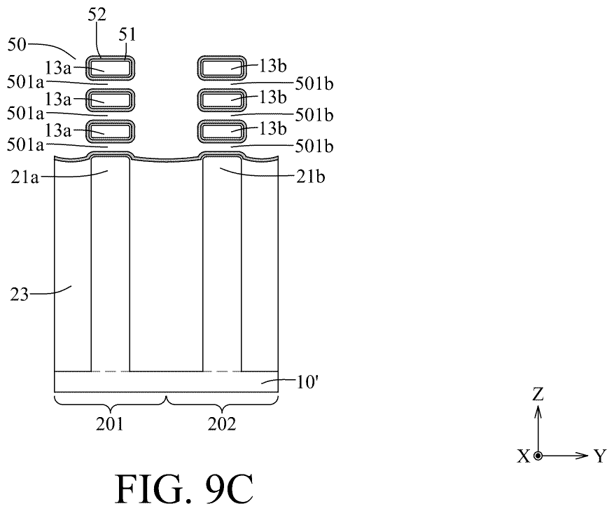

Referring to FIGS. 9A to 9C, an interfacial layer 51 is formed on portions of the channel portions 13a, 13b and portions of the protrusions 21a, 21b that are exposed to the cavity 50. The interfacial layer 51 can provide good adhesion between the channel portions 13a, 13b and a gate dielectric layer to be subsequently formed on the channel portions 13a, 13b. In some embodiments, the interfacial layer 51 are made of silicon oxide, and are formed by an oxidation reaction that happens on a surface region of each of the channel portions 13a, 13b and a surface region of each of the protrusions 21a, 21b that are exposed from the isolation structure 23.

Next, still referring to FIGS. 9A to 9C, a gate dielectric layer 52 is formed on the interfacial layer 51. In some embodiments, the gate dielectric layer 52 is also formed on the inner spacers 36, the gate spacers 35, the CESL 43, the ILD layer 44, and the isolation structure 23. In some embodiments, the gate dielectric layer 52 includes a metal-containing high-k dielectric layer (having a k-value not less than about 9, or in other embodiments, greater than about 30), such as metal oxides of hafnium, tantalum, titanium, zirconium, aluminum, lanthanum, yttrium, other suitable metals, other suitable elements (e.g., silicon), or combinations thereof.

The gate dielectric layer 52 has a first portion on the first region 201, and a second portion on the second region 202. In some embodiments, multiple dipole processes may be performed to introduce an n-type dipole element into the first portion of the gate dielectric layer 52 so as to adjust the threshold voltage of the NMOS device 301, and to introduce a p-type dipole element into the second portion of the gate dielectric layer 52 so as to adjust the threshold voltage of the PMOS device 302. Each of the dipole processes may include forming a dipole layer (not shown) on the first portion or the second portion of the gate dielectric layer 52, performing a thermal process to drive the n-type dipole element or the p-type dipole element in the dipole layer into the first portion or the second portion of the gate dielectric layer 52, and removing the dipole layer to expose the first portion or the second portion of the gate dielectric layer 52. In some embodiments, the n-type dipole element may include La, Y, other suitable n-type dipole elements, or combinations thereof. In some embodiments, the p-type dipole element may include Al, Ti, other suitable p-type dipole elements, or combinations thereof. In some embodiments, the dipole layer used in each of the dipole processes includes metal oxide including the n-type dipole element or the p-type dipole element.

As shown in FIG. 9C, the spaces 501a, 501b are still present but are slightly reduced due to formation of the gate dielectric layer 52. The structure shown in FIGS. 9A to 9C is obtained after step S07 of the method 100 as shown in FIG. 1.

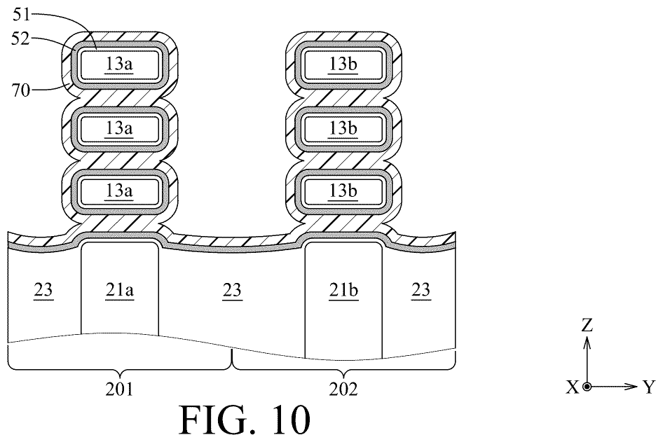

FIGS. 10 to 20C illustrate the intermediate stages in formation of a gate electrode 60 in accordance with some embodiments. The gate electrode 60 (see FIG. 20C) is formed on the gate dielectric layer 52, and is configured as a multi-layered structure. The gate electrode 60 and the gate dielectric layer 52 collectively constitute a gate structure. The gate structure extends along surfaces of the upper portion of the active region (i.e., the channel portions 13a, 13b) and an upper surface of the isolation structure 23. In some embodiments not shown herein, the gate structure has a curved top surface.

Referring to FIG. 10, a blocking layer 70 is conformally formed on the gate dielectric layer 52, and has a thickness sufficient to fill the spaces 501a, 501b (see FIG. 9C). In some embodiments, the blocking layer 70 includes a dielectric material that is different from the dielectric material of the gate dielectric layer 52, so that the blocking layer 70 may be selectively removed in a subsequent step, and the gate dielectric layer 52 is substantially intact due to different etching rates thereof. In some embodiments, possible dielectric materials suitable for the blocking layer 70 include an oxide (such as silicon oxide, aluminum oxide, hafnium oxide, or zirconium oxide), a nitride (such as silicon nitride, aluminum nitride, or titanium nitride), other suitable dielectric materials, or combinations thereof. In some embodiments, the blocking layer 70 is formed by CVD, ALD, or other suitable deposition techniques.

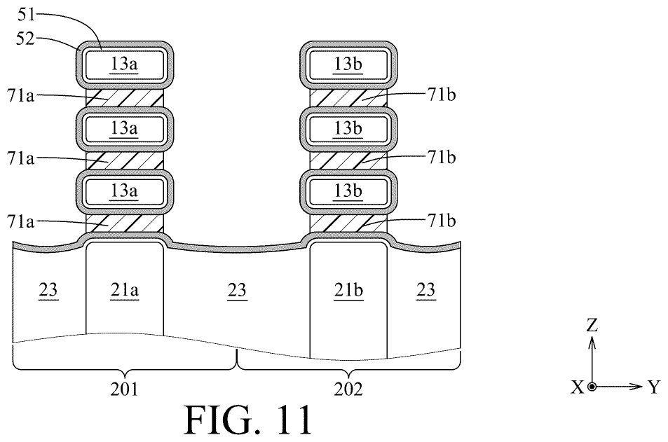

Referring to FIG. 11, an etching process is performed on the blocking layer 70 to remove portions of the blocking layer 70, so that the blocking layer 70 is formed into blocking portions 71a respectively located beneath the channel portions 13a, and blocking portions 71b respectively located beneath the channel portions 13b.

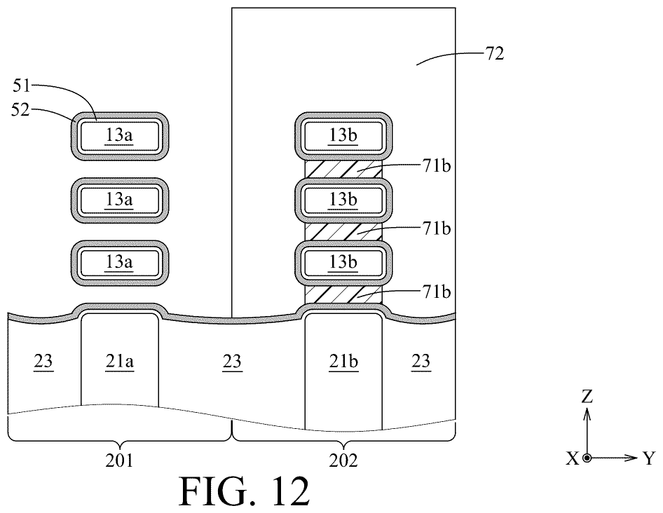

Referring to FIG. 12, a patterned mask layer 72 is formed such that the structure at the second region 202 is covered by the patterned mask layer 72, and the structure at the first region 201 is exposed from the patterned mask layer 72. Next, the blocking portions 71a are removed by a selective etching process without damaging the first portion of the gate dielectric layer 52 on the first region 201. Then, the patterned mask layer 72 is removed before proceeding to the next step.

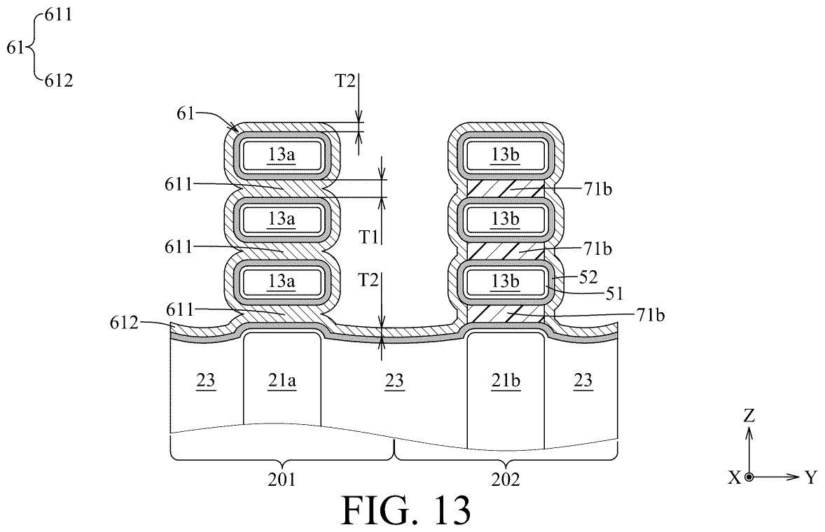

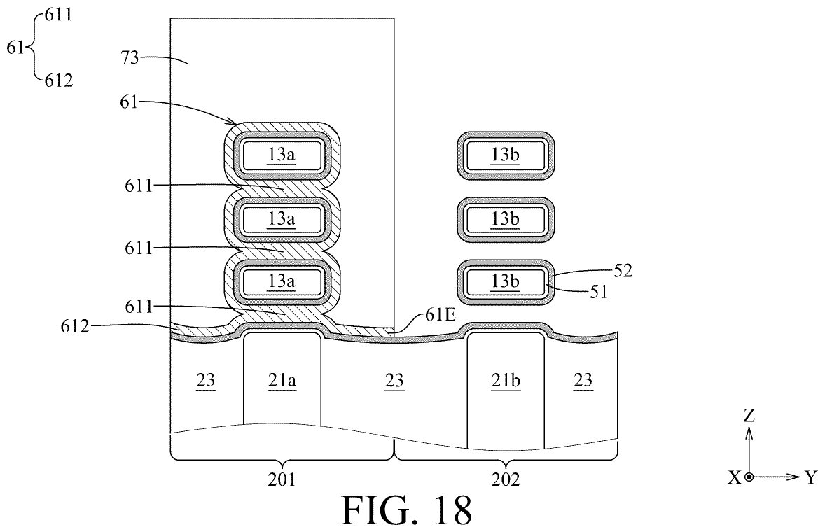

Referring to FIG. 13, an n-type work function layer 61 is formed. The n-type work function layer 61 includes a first portion formed on the first region 201 and a second portion formed on the second region 202. It is noted that the second portion of the n-type work function layer 61 will be removed in the next step (see the example shown in FIG. 18), while the first portion of the n-type work function layer 61 remains and is used to adjust the threshold voltage of the NMOS device 301.

As shown in FIG. 13, the n-type work function layer 61 is disposed around the channel portions 13a, and is separated from the channel portions 13a through the first portion of the gate dielectric layer 52 on the first region 201. The n-type work function layer 61 is further formed on an upper surface of the protrusion 21a and the upper surface of the isolation structure 23. Since the presence of the blocking portions 71b, the n-type work function layer 61 is formed on an uppermost surface and side surfaces of the channel portions 13b, and side surfaces of the blocking portions 71b.

The n-type work function layer 61 includes an n-type work function material in a crystalline structure and an n-type stressor element. The n-type stressor element is doped in the n-type work function material, and is present in an amount sufficient to permit the first portion of the n-type work function layer 61 to apply a tensile stress on the channel portions 13a. In some embodiments, the n-type work function material has a work function energy ranging from about 3.8 eV to about 4.5 eV, and may include TiAl, TiAlN, TiAlC, TaAlSiC, TaAlC, TaAlSiC, other suitable n-type work function materials, or combinations thereof. The n-type stressor element includes a metal element that is different from the metal element in the n-type work function material. The n-type stressor element may be substitutionally (i.e., non-interstitially) doped in the n-type work function material. That is, the n-type stressor element tends to be located in a substitutional lattice site rather than an interstitial lattice site. Furthermore, the substitutional lattice site is a location where a majority metal element of the n-type work function material may be located. The selection of the n-type stressor element is based on criteria as described below.

The n-type work function material has a first crystalline phase with a first lattice constant, and a majority metal element of the n-type work function material has a first atomic radius. The n-type stressor element has a second atomic radius, and a crystal structure of the n-type stressor element has a second crystalline phase with a second lattice constant. When the second crystalline phase is the same as the first crystalline phase, the second lattice constant is selected to be less than the first lattice constant. When the second crystalline phase is different from the first crystalline phase, the second atomic radius is selected to be less than the first atomic radius. In some embodiments, the n-type stressor element may include Cr, Mn, or a combination thereof.

The n-type work function material doped with the n-type stressor element may have a stressed lattice that has an atomic spacing smaller than that of a normal lattice without being stressed. That is, the lattice constant of the n-type work function material doped with the n-type stressor element is smaller than the lattice constant of the n-type work function material without being doped with the n-type stressor element. Hence, the n-type work function layer 61 is formed as a compressive film and induces a tensile stress to be applied on the channel portions 13a. A lattice distortion may occur within a surface region of each channel portion 13a proximate to the n-type work function layer 61. In some embodiments, an average distance (i.e., an average atomic spacing) between atoms in the surface region of each channel portion 13a is increased by about 0.1% to about 3%. The mobility of electrons within the channel portions 13a may be increased by about 10% to about 200%.

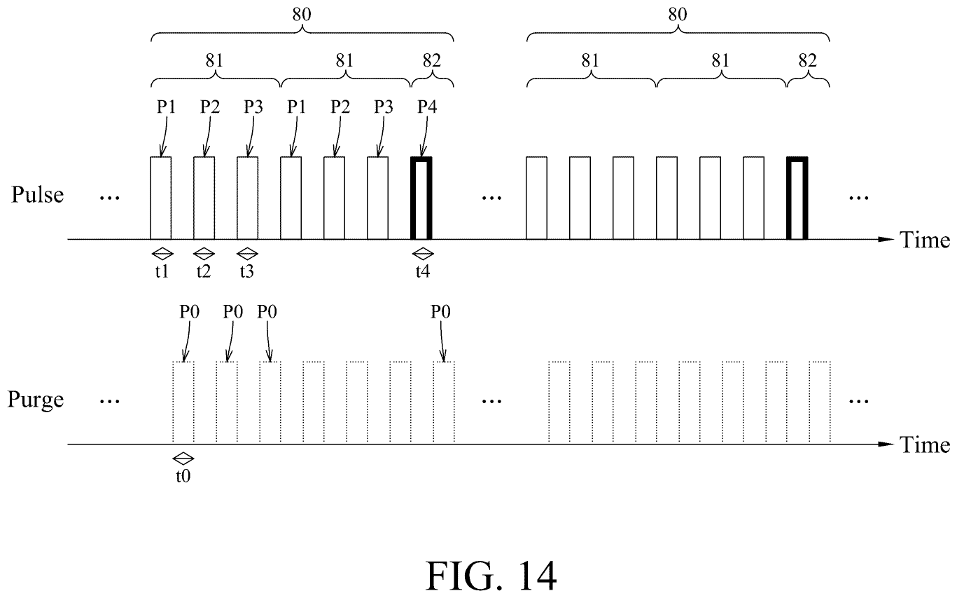

In some embodiments, the n-type work function layer 61 may be formed by ALD (including thermal atomic layer deposition (thermal ALD) or plasma-enhanced atomic layer deposition (PEALD)). FIG. 14 is a schematic diagram illustrating a time sequence of pulse steps and purge steps in an atomic layer deposition process for forming the n-type work function layer 61 in accordance with some embodiments. The atomic layer deposition process for forming the n-type work function layer 61 includes first deposition cycles 81 and second deposition cycles 82. In each of the first deposition cycles 81, a monolayer of the n-type work function material is formed on the gate dielectric layer 52. In each of the second deposition cycles 82, a monolayer of the n-type stressor element is formed on a monolayer of the n-type work function material that is formed in a previous deposition cycle.

In some exemplary embodiments, the n-type work function material includes, for example, but not limited to, TiAlN, and the n-type stressor element includes, for example, but not limited to, Cr. In such case, each of the first deposition cycles 81 includes sequentially performing a first pulse step P1 for a first pulse time period t1, a second pulse step P2 for a second pulse time period t2, and a third pulse step P3 for a third pulse time period t3. In some embodiments, a titanium-containing precursor gas is introduced into an ALD process chamber during the first pulse step P1, an aluminum-containing precursor gas is introduced into the ALD process chamber during the second pulse step P2, and a nitrogen-containing reactant gas is introduced into the ALD process chamber during the third pulse step P3. Each of the second deposition cycles 82 includes performing a fourth pulse step P4 for a fourth pulse time period t4, and a chromium-containing precursor gas is introduced into the ALD process chamber during the fourth pulse step P4. Each of the pulse steps P1, P2, P3, P4 is followed by a corresponding one of the purge steps P0 for a purge time period t0, so as to purge a remainder of the precursor gas or the reactant gas from the ALD process chamber before proceeding to the next pulse step. The time periods t0, t1, t2, t3, t4 exemplarily shown in FIG. 14 are substantially the same as or similar to each other, but are not limited thereto. Each of the time periods t0, t1, t2, t3, t4 may vary according to practical applications. In some embodiments, when PEALD is used to form the n-type work function layer 61, the nitrogen-containing reactant gas, prior to being introduced into the ALD process chamber, may be formed into a plasma state using, for example, a remote plasma generator, so that the temperature for forming the n-type work function layer 61 can be reduced.

The average concentration of the n-type stressor element in the n-type work function layer 61 may be adjusted by controlling a ratio of a total number of the first deposition cycles 81 to a total number of the first deposition cycles 82. In some embodiments, the total number of the second deposition cycles 82 is less than the total number of the first deposition cycles 81, such that an average atomic concentration of the n-type stressor element in the n-type work function layer 61 ranges from about 0.5% to about 10%. When the average atomic concentration of the n-type stressor element in the n-type work function layer 61 is too small (e.g., less than about from 0.5%), the n-type work function layer 61 is less likely to induce a tensile stress to be applied on the channel portions 13a. When the average atomic concentration of the n-type stressor element in the n-type work function layer 61 is too large (e.g., greater than about from 10%), the threshold voltage of the NMOS device 301 may shift to an undesired value.

In the exemplary method shown in FIG. 14, the n-type stressor element is doped in the n-type work function material in an in-situ doping manner. Any one of the second deposition cycles 82 is performed between one or more of the first deposition cycles 81 and another one or more of the first deposition cycles 81.

For example, the atomic layer deposition process for forming the n-type work function layer 61 may include process cycles 80 that are repeatedly performed. Each of the process cycles 80 includes a first number of the first deposition cycles 81 and a second number of the second deposition cycles 82. Each of the first number and the second number is a positive integer, and the first number is greater than the second number. In the case that a ratio of the first number to the second number in each process cycle 80 is a fixed value, the concentration of the n-type stressor element in the n-type work function layer 61 thus obtained may be relatively uniform. In the case that the ratio of the first number to the second number in each process cycle 80 gradually increases over time, the n-type stressor element in the n-type work function layer 61 thus obtained may have concentrations gradually decreasing in a direction away from the gate dielectric layer 52.

In some embodiments, a thermal treatment may be optionally performed to improve the uniformity of the n-type stressor element in the n-type work function layer 61, and reduce defects in the n-type work function layer 61, thereby inducing a greater tensile stress to be applied on the channel portions 13a.

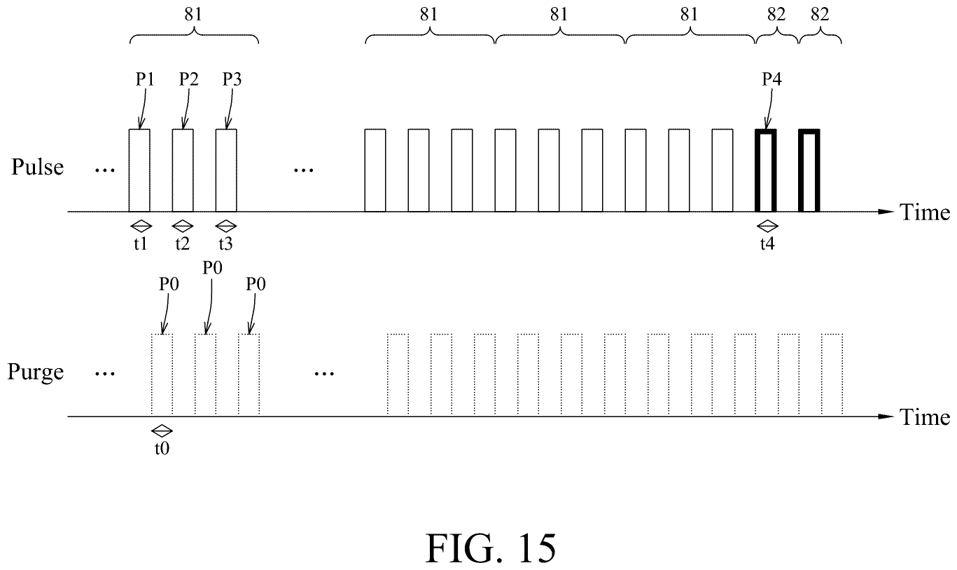

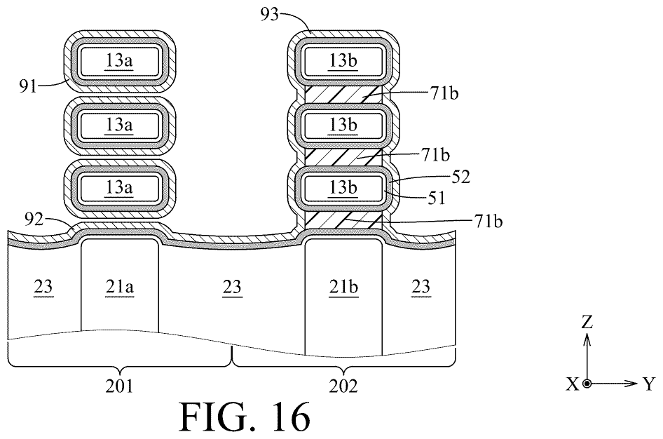

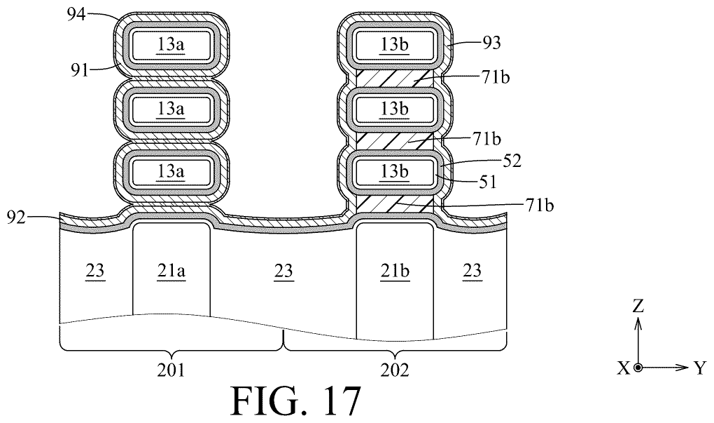

FIG. 15 is a schematic diagram similar to that of FIG. 14, but the first and second deposition cycles 81, 82 are performed in a sequence that is different from that shown in FIG. 14. In the exemplary method shown in FIG. 15, the n-type stressor element is doped in the n-type work function material in a post doping manner. At least one second deposition cycle 82 is performed after a last one of the first deposition cycles 81. FIGS. 16 and 17 illustrate the intermediate stages in formation of the n-type work function layer 61 using the post doping manner in accordance with some embodiments. Firstly, the first deposition cycles 81 are performed to form first work function portions 91, a second work function portion 92, and a third work function portion 93. The first work function portions 91 are respectively formed around the channel portions 13a. The second work function portion 92 is formed on the upper surface of the protrusion 21a and the upper surface of the isolation structure 23. The third work function portion 93 is formed on the uppermost surface and the side surfaces of the channel portions 13b, and the side surfaces of the blocking portions 71b. It is noted that, by adjusting the number of the first deposition cycles 81, two adjacent ones of the first work function portions 91 are prevented from merging together at a location between two corresponding adjacent ones of the channel portions 13a, and the second work function portion 92 and a bottommost one of the first work function portions 91 are prevented from merging together at a location between the protrusion 21a and a bottommost one of the channel portions 13a. Next, the at least one second deposition cycle 82 is performed to form a doping layer 94, which includes the n-type stressor element, on the work function portions 91, 92, 93. In some embodiments, a space between the two adjacent ones of the first work function portions 91, and a space between the second work function portion 92 and the bottommost one of the first work function portions 91 may be filled by the doping layer 94. Then, a thermal treatment is performed to drive the n-type stressor element in the doping layer 94 into the work function portions 91, 92, 93 so as to form the n-type work function layer 61 (see FIG. 13). In such case, the n-type stressor element in the n-type work function layer 61 thus obtained may have concentrations gradually decreasing in a direction toward the gate dielectric layer 52.

In some alternative embodiments, the n-type work function layer 61 may be formed by PVD, followed by the thermal treatment. That is, the work function portions 91, 92, 93, and the doping layer 94 may be formed by PVD, and then the thermal treatment is performed to drive the n-type stressor element in the doping layer 94 into the work function portions 91, 92, 93 so as to form the n-type work function layer 61.

Referring to FIG. 13, the first portion of the n-type work function layer 61 on the first region 201 includes inner layer portions 611 and an outer layer portion 612. Each of the inner layer portions 611 is disposed between two corresponding adjacent ones of the channel portions 13a and the protrusion 21a. In some embodiments, each of the inner layer portions 611 has a thickness T1 ranging from about 3 nm to about 6 nm. The outer layer portion 612 is disposed over an uppermost surface and side surfaces of the channel portions 13a, and an upper surface of a portion of the isolation structure 23 disposed alongside the protrusion 21a. In some embodiments, the outer layer portion 612 has a thickness T2 ranging from about 1.5 nm to about 4 nm. In some embodiments, the thickness T2 is less than the thickness T1. Each of the inner layer portions 611 has two ends which are opposite to each other in the Y direction and which are connected to the outer layer portion 612.

The n-type stressor element is present in each of the outer layer portion 612 and the inner layer portions 611. The distribution of the n-type stressor element in the n-type work function layer 61 mainly depends on the method for doping the n-type stressor element as described above.

In some embodiments, the concentration of the n-type stressor element in each of the outer layer portion 612 and the inner layer portions 611 may be uniform.

In some other embodiments, the concentrations of the n-type stressor element in each of the inner layer portions 611 may have a minimum value at a location that is close to halfway between two corresponding adjacent ones of the channel portions 13a and the protrusion 21a, and gradually increase toward each of the two corresponding adjacent ones of the channel portions 13a and the protrusion 21a. Furthermore, the concentrations of the n-type stressor element in the outer layer portion 612 gradually increases from an outer surface of the outer layer portion 612 toward the interface between the outer layer portion 612 and the first portion of the gate dielectric layer 52 on the first region 201.

In still other embodiments, the concentrations of the n-type stressor element in each of the inner layer portions 611 may have a maximum value at a location that is close to halfway between two corresponding adjacent ones of the channel portions 13a and the protrusion 21a, and gradually decrease toward each of the two corresponding adjacent ones of the channel portions 13a and the protrusion 21a. Furthermore, the concentrations of the n-type stressor element in the outer layer portion 612 gradually decreases from the outer surface of the outer layer portion 612 toward an interface between the outer layer portion 612 and the first portion of the gate dielectric layer 52 on the first region 201.

Referring to FIG. 18, a patterned mask layer 73 is formed such that the structure at the first region 201 is covered by the patterned mask layer 73, and the structure at the second region 202 is exposed from the patterned mask layer 73. Next, the second portion of the n-type work function layer 61 and the blocking portions 71b on the second region 202 are removed by a selective etching process without damaging the second portion of the gate dielectric layer 52 on the second region 202. Accordingly, the outer layer portion 612 of the n-type work function layer 61 has a boundary region 61E exposed from the patterned mask layer 73. Then, the patterned mask layer 73 is removed before proceeding to the next step.

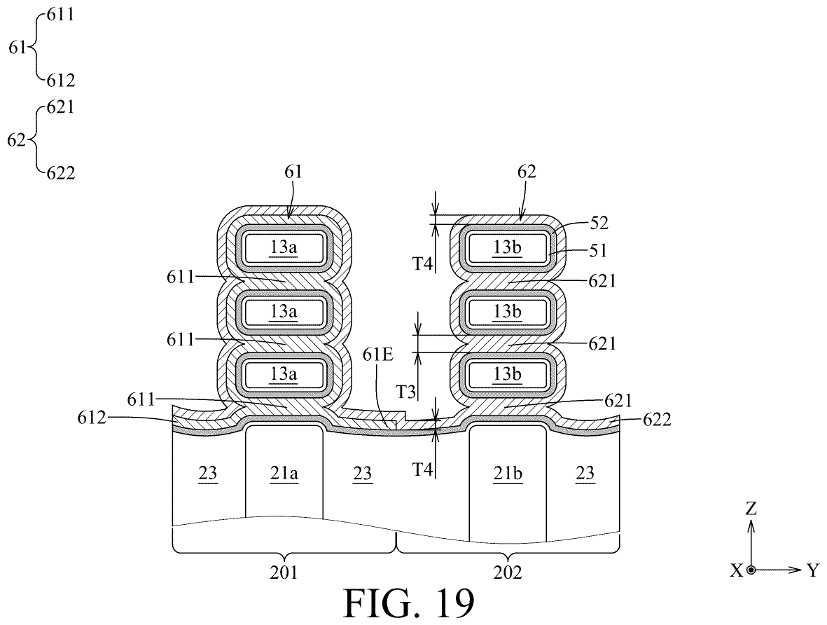

Referring to FIG. 19, a p-type work function layer 62 is formed. The p-type work function layer 62 is disposed around the channel portions 13b, and is separated from the channel portions 13b through the second portion of the gate dielectric layer 52 on the second region 202. The p-type work function layer 62 is used to adjust the threshold voltage of the PMOS device 302. The p-type work function layer 62 is further formed on an upper surface of the protrusion 21b, the upper surface of the isolation structure 23, and the outer surface of the outer layer portion 612 of the n-type work function layer 61. In some embodiments, the p-type work function layer 62 has a stepped profile at a location of the boundary region 61E of the outer layer portion 612 of the n-type work function layer 61 above a portion of the isolation structure 23 between the protrusions 21a, 21b. It is noted that the threshold voltage of the NMOS device 301, and the type and magnitude of the induced stress applied on the channel portions 13a of the NMOS device 301 are mainly dominated by the first portion of the n-type work function layer 61 on the first region 201, because a distance from each channel portion 13a to the first portion of the n-type work function layer 61 is less than a distance from each channel portion 13a to a first portion of the p-type work function layer 62 on the first region 201.

The p-type work function layer 62 includes a p-type work function material in a crystalline structure and a p-type stressor element. The p-type stressor element is doped in the p-type work function material, and is present in an amount sufficient to permit a second portion of the p-type work function layer 62 on the second region 202 to apply a compressive stress on the channel portions 13b. In some embodiments, the p-type work function material has a work function energy ranging from about 4.7 eV to about 5.2 eV, and may include W, Co, Ti, Ni, Mo, TiN, TiSiN, WCN, TiWN, TaN, other suitable p-type work function materials, or combinations thereof. The p-type stressor element includes a metal element that is different from the metal element in the p-type work function material. The p-type stressor element may be substitutionally (i.e., non-interstitially) doped in the p-type work function material. That is, the p-type stressor element tends to be located in a substitutional lattice site rather than an interstitial lattice site. Furthermore, the substitutional lattice site is a location where a majority metal element of the p-type work function material may be located. The selection of the p-type stressor element is based on criteria as described below.

The p-type work function material has a third crystalline phase with a third lattice constant, and a majority metal element of the p-type work function material has a third atomic radius. The p-type stressor element has a fourth atomic radius, and a crystal structure of the p-type stressor element has a fourth crystalline phase with a fourth lattice constant. When the fourth crystalline phase is the same as the third crystalline phase, the fourth lattice constant is selected to be greater than the third lattice constant. When the fourth crystalline phase is different from the third crystalline phase, the fourth atomic radius is selected to be greater than the third atomic radius. In some embodiments, the p-type stressor element may include Sn, Pb, or a combination thereof.

The p-type work function material doped with the p-type stressor element may have a stressed lattice that has an atomic spacing greater than that of a normal lattice without being stressed. That is, the lattice constant of the p-type work function material doped with the p-type stressor element is greater than the lattice constant of the p-type work function material without being doped with the p-type stressor element. Hence, the p-type work function layer 62 is formed as a tensile film and induces a compressive stress to be applied on the channel portions 13b. A lattice distortion may occur within a surface region of each channel portion 13b proximate to the p-type work function layer 62. In some embodiments, an average distance (i.e., an average atomic spacing) between atoms in the surface region of each channel portion 13b is decreased by about 0.1% to about 3%. The mobility of holes within the channel portions 13b may be increased by about 10% to about 200%.

In some embodiments, the p-type work function layer 62 may be formed in a manner similar to that for forming the n-type work function layer 61 as described above with reference to FIGS. 14 to 17 (i.e., the p-type stressor element may be doped in an in-situ doping or a post doping manner), except that precursor or reactant gases used for forming the p-type work function layer 62 are different from the precursor or reactant gases used for forming the n-type work function layer 61.

For example, in some exemplary embodiments, the p-type work function material includes, for example, but not limited to, TiN, and the p-type stressor element includes, for example, but not limited to, Sn. In such case, a time sequence of pulse steps and purge steps in an atomic layer deposition process for forming the p-type work function layer 62 may be similar to the time sequence shown in FIG. 14 or FIG. 15, but the second pulse step P2 and a corresponding one of the purge steps P0 performed after the second pulse step P2 in each of the first deposition cycles 81 are omitted. That is, in each of the first deposition steps 81, a titanium-containing precursor gas is introduced into an ALD process chamber during the first pulse step P1, and a nitrogen-containing reactant gas is introduced into the ALD process chamber during the third pulse step P3. In each of the second deposition cycles 82, a tin-containing precursor gas is introduced into the ALD process chamber during the fourth pulse step P4.

In the case that the p-type stressor element is doped in the p-type work function material in an in-situ doping manner which is the same as or similar to the in-situ doping manner as described above with reference to FIG. 14, the distribution of the p-type stressor element in the p-type work function layer 62 mainly depends on whether the ratio of the first number of the first deposition cycles 81 to the second number of the second deposition cycles 82 in each process cycle 80 is consistent, gradually increasing, or gradually decreasing over time.

In the case that the p-type stressor element is doped in the p-type work function material in a post doping manner which is the same as or similar to the post doping manner as described above with reference to FIGS. 15 to 17, the configuration of the work function portions 91, 92, 93 shown in FIG. 16 may have the differences below. The first work function portions 91 may be respectively formed around the channel portions 13b. The second work function portion 92 may be formed on the upper surface of the protrusion 21b and the upper surface of the isolation structure 23. The third work function portion 93 may be formed on the outer surface of the outer layer portion 612 of the n-type work function layer 61. Then, the p-type stressor element in the doping layer 94 is driven into the work function portions 91, 92, 93 so as to form the p-type work function layer 62. The p-type stressor element in the p-type work function layer 62 thus obtained may have concentrations gradually decreasing in a direction toward the gate dielectric layer 52.

Referring to FIG. 19, the second portion of the p-type work function layer 62 on the second region 202 includes inner layer portions 621 and an outer layer portion 622. Each of the inner layer portions 621 is disposed between two corresponding adjacent ones of the channel portions 13b and the protrusion 21b. In some embodiments, each of the inner layer portions 621 has a thickness T3 ranging from about 3 nm to about 6 nm. The outer layer portion 622 is disposed over the uppermost surface and the side surfaces of the channel portions 13b, and an upper surface of a portion of the isolation structure 23 disposed alongside the protrusion 21b. In some embodiments, the outer layer portion 622 has a thickness T4 ranging from about 1.5 nm to about 4 nm. In some embodiments, the thickness T4 is less than the thickness T3. Each of the inner layer portions 621 has two ends which are opposite to each other in the Y direction and which are connected to the outer layer portion 622.

The p-type stressor element is present in each of the outer layer portion 622 and the inner layer portions 621. The distribution of the p-type stressor element in the p-type work function layer 62 mainly depends on the method for doping the p-type stressor element as described above.

In some embodiments, the concentration of the p-type stressor element in each of the outer layer portion 622 and the inner layer portions 621 may be uniform.

In some other embodiments, the concentrations of the p-type stressor element in each of the inner layer portions 621 may have a minimum value at a location that is close to halfway between two corresponding adjacent ones of the channel portions 13b and the protrusion 21b, and gradually increase toward each of the two corresponding adjacent ones of the channel portions 13b and the protrusion 21b. In addition, the concentrations of the p-type stressor element in the outer layer portion 622 gradually increases from an outer surface of the outer layer portion 622 toward the interface between the outer layer portion 622 and the second portion of the gate dielectric layer 52 on the second region 202. Furthermore, the concentrations of the p-type stressor element in the first portion of the p-type work function layer 62 on the first region 201 gradually increases from an outer surface of the first portion of the p-type work function layer 62 toward an interface between the first portion of the p-type work function layer 62 and the outer layer portion 612 of the first portion of the n-type work function layer 61.

In still other embodiments, the concentrations of the p-type stressor element in each of the inner layer portions 621 may have a maximum value at a location that is close to halfway between two corresponding adjacent ones of the channel portions 13b and the protrusion 21b, and gradually decrease toward each of the two corresponding adjacent ones of the channel portions 13b and the protrusion 21b. In addition, the concentrations of the n-type stressor element in the outer layer portion 622 gradually decreases from the outer surface of the outer layer portion 622 toward an interface between the outer layer portion 622 and the second portion of the gate dielectric layer 52 on the second region 202. Furthermore, the concentrations of the p-type stressor element in the first portion of the p-type work function layer 62 on the first region 201 gradually decreases from the outer surface of the first portion of the p-type work function layer 62 toward the interface between the first portion of the p-type work function layer 62 and the outer layer portion 612 of the first portion of the n-type work function layer 61.

Referring to FIGS. 20A to 20C, a gate fill portion 63 is formed to fill the cavity 50 using CVD, ALD or other suitable deposition techniques, followed by a planarization process (e.g., CMP) to expose the ILD layer 44, thereby obtaining the gate electrode 60. The gate fill portion 63 is in contact with the p-type work function layer 62. The gate fill portion 63 is provided for increasing electrical conductivity of the gate electrode 60, and includes tungsten (W), cobalt (Co), ruthenium (Ru), iridium (Ir), other suitable high conductivity materials, or combinations thereof. In some embodiments, the gate electrode 60 includes a seam. In some embodiments, the gate fill portion 63 is formed with the seam. In some embodiments, the seam is located between the gate spacers 35. In some embodiments, the upper surface of the isolation structure 23 is non-planar when viewed along the X direction. The structure shown in FIGS. 20A to 20C is obtained after step S08 of the method 100 as shown in FIG. 1.

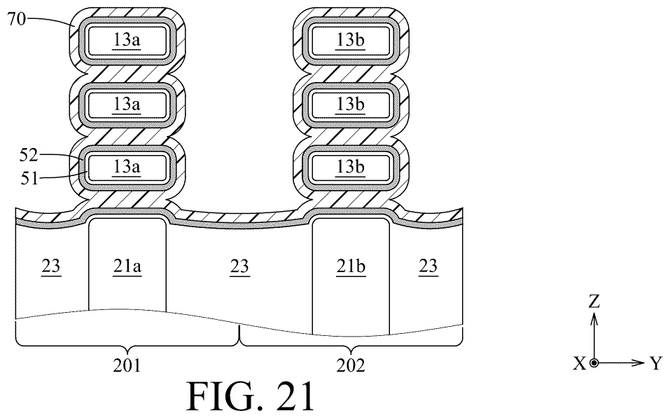

FIGS. 21 to 27C illustrate the intermediate stages in formation of a gate electrode 60′ in accordance with some alternative embodiments. The gate electrode 60′ is formed in a manner similar to that for forming the gate electrode 60 as described above with reference to FIGS. 10 to 20C, but the p-type work function layer 62 is formed before forming the n-type work function layer 61. Only the differences will be described in the following. Similar numerals from the above-mentioned embodiments have been used where appropriate, with some construction differences being indicated with different numerals.

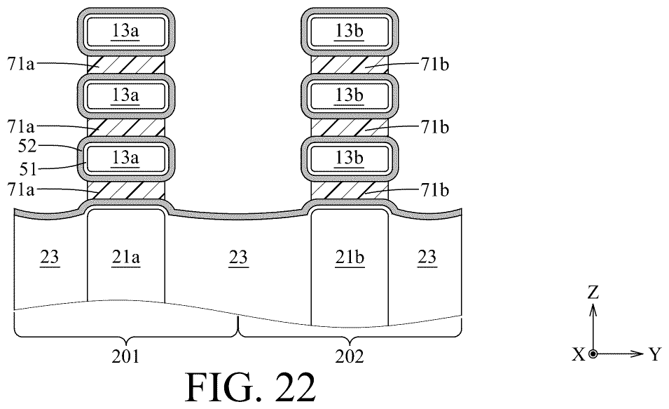

FIGS. 21 and 22 are views respectively similar to those of FIGS. 10 and 11, and thus details thereof are omitted for the sake of brevity.

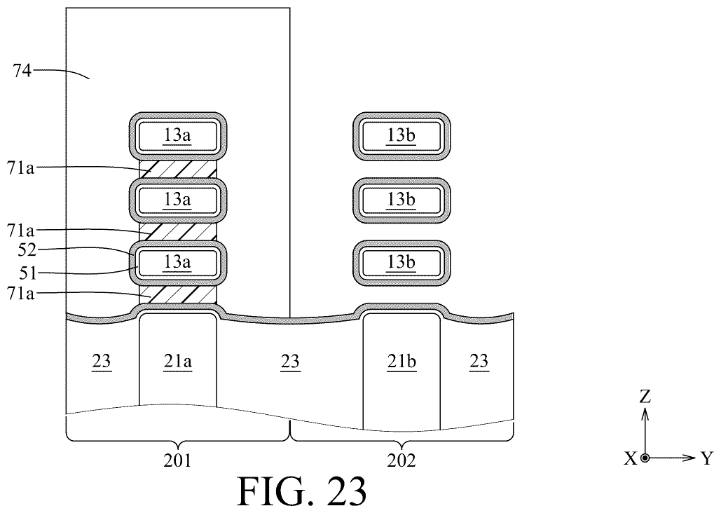

FIG. 23 is a view similar to that of FIG. 12, but a patterned mask layer 74 is formed such that the structure at the first region 201 is covered by the patterned mask layer 74, and the structure at the second region 202 is exposed from the patterned mask layer 74. Next, the blocking portions 71b are removed by a selective etching process without damaging the second portion of the gate dielectric layer 52 on the second region 202. Then, the patterned mask layer 74 is removed before proceeding to the next step.

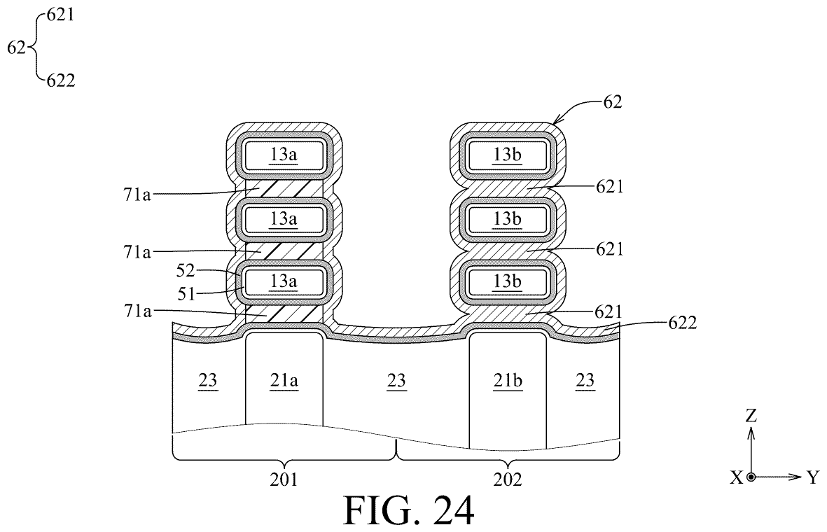

Referring to FIG. 24, the p-type work function layer 62 is formed. Possible materials and processes for forming the p-type work function layer 62 are described above with reference to FIG. 19, and thus details thereof are omitted for the sake of brevity. The p-type work function layer 62 shown in FIG. 24 has a structure that is the same as or similar to that of the p-type work function layer 62 shown in FIG. 19, but the first portion of the p-type work function layer 62 on the first region 201 is formed on the uppermost surface and the side surfaces of the channel portions 13a, and side surfaces of the blocking portions 71a.

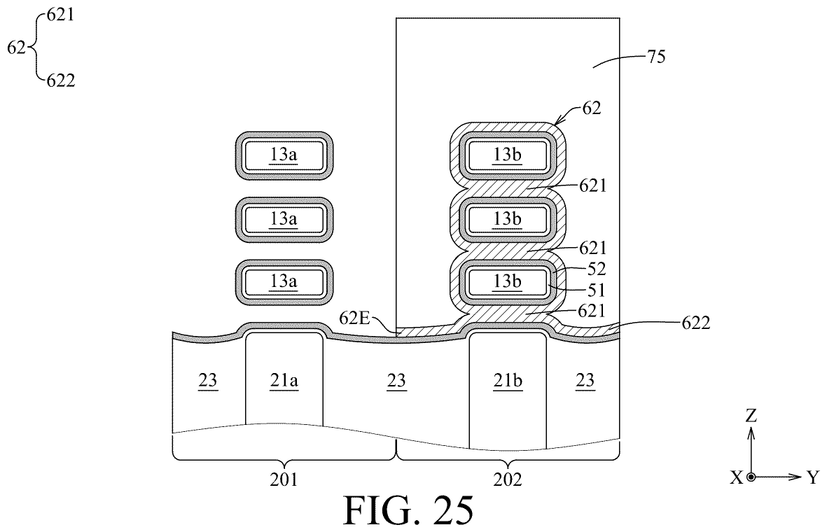

Referring to FIG. 25, a patterned mask layer 75 is formed such that the structure at the second region 202 is covered by the patterned mask layer 75, and the structure at the first region 201 is exposed from the patterned mask layer 75. Next, the first portion of the p-type work function layer 62 and the blocking portions 71a on the first region 201 are removed by a selective etching process without damaging the first portion of the gate dielectric layer 52 on the first region 201. Accordingly, the outer layer portion 622 of the second portion of the p-type work function layer 61 on the second region 202 has a boundary region 62E exposed from the patterned mask layer 75. Then, the patterned mask layer 75 is removed before proceeding to the next step.

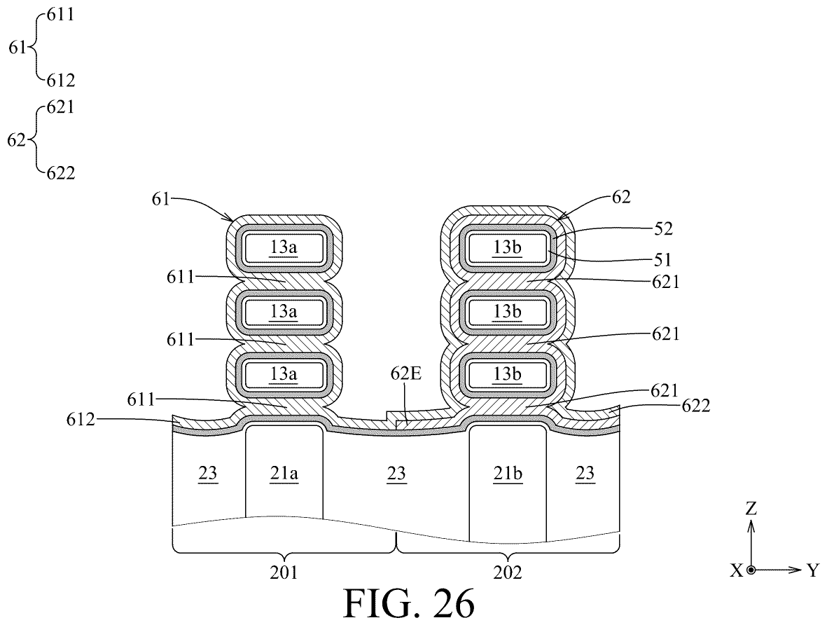

Referring to FIG. 26, the n-type work function layer 61 is formed. Possible materials and processes for forming the n-type work function layer 61 are described above with reference to FIGS. 13 to 17, and thus details thereof are omitted for the sake of brevity. The n-type work function layer 61 shown in FIG. 26 has a structure that is the same as or similar to that of the n-type work function layer 61 shown in FIG. 13, but the second portion of the n-type work function layer 61 on the second region 202 is formed on the outer layer portion 622 of the p-type work function layer 62. In such case, the n-type work function layer 61 has a stepped profile at a location of the boundary region 62E of the outer layer portion 622 of the p-type work function layer 62 above a portion of the isolation structure 23 between the protrusions 21a, 21b. It is noted that each of the threshold voltage of the PMOS device 302, and the type and magnitude of the induced stress applied on the channel portions 13b are mainly dominated by the second portion of the p-type work function layer 62 on the second region 202, because a distance from each channel portion 13b to the second portion of the p-type work function layer 62 is less than a distance from each channel portion 13b to the second portion of the n-type work function layer 61 on the second region 202.

FIGS. 27A to 27C are views respectively similar to those of FIGS. 20A to 20C, but the gate fill portion 63, which is formed to fill the cavity 50, is in contact with the n-type work function layer 61. Possible materials and processes suitable for forming the gate fill portion 63 are described above with reference to FIGS. 20A to 20C, and thus details thereof are omitted for the sake of brevity.

In some alternative embodiments, the semiconductor structure 200 may further include additional features, and/or some features present in the semiconductor structure 200 may be modified, replaced, or eliminated without departure from the spirit and scope of the present disclosure.

In summary, with the provision of the n-type stressor element and the p-type stressor element respectively doped in the n-type work function layer 61 and the p-type work function layer 62, a tensile stress and a compressive stress may be respectively induced by the n-type work function layer 61 and the p-type work function layer 62 and respectively applied on the channel portions 13a and the channel portions 13b. The enhancement of the mobility of electrons within the channel portions 13a of the NMOS device 301 and the mobility of holes within the channel portions 13b of the PMOS device 302 may reach about 10% to about 200%.

In accordance with some embodiments of the present disclosure, a semiconductor structure includes: an active region disposed over a substrate; and a gate structure extending over a top portion of the active region, the gate structure having a curved top surface, the gate structure including a gate dielectric layer and a gate electrode over the gate dielectric layer, the gate electrode including a seam, the gate electrode including a work function layer, the work function layer including a work function material and a stressor element doped in the work function material, the stressor element including a metal element that is different from a metal element in the work function material, the stressor element being present in an amount sufficient to permit the work function layer to apply a stress on the top portion of the active region.

In accordance with some embodiments of the present disclosure, an average atomic concentration of the stressor element in the work function layer ranges from 0.5% to 10%.

In accordance with some embodiments of the present disclosure, the semiconductor device is an n-channel device. The work function material has a first crystalline phase with a first lattice constant, a majority metal element of the work function material having a first atomic radius. The stressor element has a second atomic radius, a crystal structure of the stressor element having a second crystalline phase with a second lattice constant. When the second crystalline phase is the same as the first crystalline phase, the second lattice constant is less than the first lattice constant, such that the work function layer is formed as a compressive film and induces a tensile stress to be applied on the top portion of the active region. When the second crystalline phase is different from the first crystalline phase, the second atomic radius is less than the first atomic radius, such that the work function layer is formed as a compressive film and induces a tensile stress to be applied on the top portion of the active region.

In accordance with some embodiments of the present disclosure, the work function material includes TiAl, TiAlN, TiAlC, TaAlSiC, TaAlC, TaAlSiC, or combinations thereof, the stressor element includes Cr, Mn, or a combination thereof.

In accordance with some embodiments of the present disclosure, the semiconductor device is a p-channel device. The work function material has a third crystalline phase with a third lattice constant, a majority metal element of the work function material having a third atomic radius. The stressor element has a fourth atomic radius, a crystal structure of the stressor element having a fourth crystalline phase with a fourth lattice constant. When the fourth crystalline phase is the same as the third crystalline phase, the fourth lattice constant is greater than the third lattice constant, such that the work function layer is formed as a tensile film and induces a compressive stress to be applied on the top portion of the active region. When the fourth crystalline phase is different from the third crystalline phase, the fourth atomic radius is greater than the third atomic radius, such that the work function layer is formed as a tensile film and induces a compressive stress to be applied on the top portion of the active region.

In accordance with some embodiments of the present disclosure, the work function material includes W, Co, Ti, Ni, Mo, TiN, TiSiN, WCN, TiWN, TaN, or combinations thereof, and the stressor element includes Sn, Pb, In, or combinations thereof.

In accordance with some embodiments of the present disclosure, a concentration of the stressor element in the work function layer is uniform.

In accordance with some embodiments of the present disclosure, the stressor element in the work function layer has concentrations gradually decreasing in a direction toward the top portion of the active region.

In accordance with some embodiments of the present disclosure, the stressor element in the work function layer has concentrations gradually decreasing in a direction away from the top portion of the active region.

In accordance with some embodiments of the present disclosure, the gate electrode is separated from the top portion of the active region by the gate dielectric layer. The work function layer is in contact with the gate dielectric layer.

In accordance with some embodiments of the present disclosure, the gate electrode further includes a gate fill portion disposed on the work function layer opposite to the gate dielectric layer and formed with the seam.

In accordance with some embodiments of the present disclosure, the active region further includes a base portion which is spaced apart from the top portion of the active region. The gate structure is disposed around the top portion of the active region.

In accordance with some embodiments of the present disclosure, a method for manufacturing a semiconductor structure includes: forming an active region over a substrate; forming an isolation structure over the substrate and around a lower portion of the active region; and forming a gate structure extending along surfaces of an upper portion of the active region and a top surface of the isolation structure, the gate structure having a curved top surface, the gate structure including a gate dielectric layer and a gate electrode over the gate dielectric layer, the gate electrode including a work function layer, the work function layer including a work function material and a stressor element doped in the work function material, the stressor element including a metal element that is different from a metal element in the work function material, the stressor element being present in an amount sufficient to permit the work function layer to apply a stress on the upper portion of the active region.

In accordance with some embodiments of the present disclosure, the upper portion of the active region includes channel portions spaced apart from each other and surrounded by the work function layer. The work function layer includes inner layer portions each disposed between two corresponding ones of the channel portions, and an outer layer portion connected to the inner layer portions. The stressor element is present in the outer layer portion and the inner layer portions.

In accordance with some embodiments of the present disclosure, formation of the gate electrode includes: depositing the work function material to form work function portions respectively around the channel portions; before two adjacent ones of the work function portions merge together at a location between two corresponding adjacent ones of the channel portions, forming a doping layer on the work function portions, the doping layer including the stressor element; and performing a thermal treatment to drive the stressor element in the doping layer into the work function portions, and to form the work function layer.

In accordance with some embodiments of the present disclosure, the work function layer is formed by atomic layer deposition. The atomic layer deposition includes first deposition cycles, each of which includes forming a monolayer of the work function material on the gate dielectric layer, and second deposition cycles, each of which includes forming a monolayer of the stressor element on the monolayer of the work function material. A total number of the second deposition cycles is less than a total number of the first deposition cycles, such that an average atomic concentration of the stressor element in the work function layer ranges from 0.5% to 10%.

In accordance with some embodiments of the present disclosure, when the work function material includes TiAl, TiAlN, TiAlC, TaAlSiC, TaAlC, TaAlSiC, or combinations thereof, the stressor element includes Cr, Mn, or a combination thereof. When the work function material includes W, Co, Ti, Ni, Mo, TiN, TiSiN, WCN, TiWN, TaN, or combinations thereof, the stressor element includes Sn, Pb, In, or combinations thereof.

In accordance with some embodiments of the present disclosure, a method for manufacturing a semiconductor structure includes: forming a first channel region and a second channel region over a substrate and extending lengthwise along a direction; forming an isolation structure over the substrate and between the first channel region and the second channel region, a top surface of the isolation structure is non-planar when viewed along the direction; and forming a gate structure extending along surfaces of the first channel region, the second channel region and a top surface of the isolation structure, the gate structure including a gate dielectric layer and a gate electrode over the gate dielectric layer. The gate electrode includes a first work function layer disposed on the first channel region and separated from the first channel region by a first portion of the gate dielectric layer, and a second work function layer disposed on the second channel region and separated from the second channel region by a second portion of the gate dielectric layer. The first work function layer includes a first work function material and a first stressor element doped in the first work function material, so as to generate a tensile stress to be applied on the first channel region. The first stressor element includes a metal element that is different from a metal element in the first work function material. The second work function layer includes a second work function material and a second stressor element doped in the second work function material, so as to generate a compressive stress to be applied on the second channel region. The second stressor element including a metal element that is different from a metal element in the second work function material. An atomic radius of the first stressor element is smaller than an atomic radius of the second stressor element.

In accordance with some embodiments of the present disclosure, the first work function material includes TiAl, TiAlN, TiAlC, TaAlSiC, TaAlC, TaAlSiC, or combinations thereof, the first stressor element including Cr, Mn, or a combination thereof. The second work function material includes W, Co, Ti, Ni, Mo, TiN, TiSiN, WCN, TiWN, TaN, or combinations thereof, and the second stressor element including Sn, Pb, In, or combinations thereof.

In accordance with some embodiments of the present disclosure, the second work function layer further extends to be disposed on the first work function layer. The second work function layer has a stepped profile a location above the isolation structure.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
an active region disposed over a substrate; and
a gate structure extending over a top portion of the active region, the gate structure having a curved top surface, the gate structure including a gate dielectric layer and a gate electrode over the gate dielectric layer, the gate electrode including a seam, the gate electrode including a work function layer, the work function layer including a work function material and a stressor element doped in the work function material, the stressor element including a metal element that is different from a metal element in the work function material, the stressor element being present in an amount sufficient to permit the work function layer to apply a stress on the top portion of the active region.

2. The semiconductor device as claimed in claim 1, wherein an average atomic concentration of the stressor element in the work function layer ranges from 0.5% to 10%.

3. The semiconductor device as claimed in claim 1, wherein
the semiconductor device is an n-channel device,
the work function material has a first crystalline phase with a first lattice constant, a majority metal element of the work function material having a first atomic radius,
the stressor element has a second atomic radius, a crystal structure of the stressor element having a second crystalline phase with a second lattice constant,
when the second crystalline phase is the same as the first crystalline phase, the second lattice constant is less than the first lattice constant, such that the work function layer is formed as a compressive film and induces a tensile stress to be applied on the top portion of the active region, and
when the second crystalline phase is different from the first crystalline phase, the second atomic radius is less than the first atomic radius, such that the work function layer is formed as a compressive film and induces a tensile stress to be applied on the top portion of the active region.

4. The semiconductor device as claimed in claim 3, wherein the work function material includes TiAl, TiAlN, TiAlC, TaAlSiC, TaAlC, TaAlSiC, or combinations thereof, the stressor element includes Cr, Mn, or a combination thereof.

5. The semiconductor device as claimed in claim 1, wherein
the semiconductor device is a p-channel device,
the work function material has a third crystalline phase with a third lattice constant, a majority metal element of the work function material having a third atomic radius,
the stressor element has a fourth atomic radius, a crystal structure of the stressor element having a fourth crystalline phase with a fourth lattice constant,
when the fourth crystalline phase is the same as the third crystalline phase, the fourth lattice constant is greater than the third lattice constant, such that the work function layer is formed as a tensile film and induces a compressive stress to be applied on the top portion of the active region, and
when the fourth crystalline phase is different from the third crystalline phase, the fourth atomic radius is greater than the third atomic radius, such that the work function layer is formed as a tensile film and induces a compressive stress to be applied on the top portion of the active region.

6. The semiconductor device as claimed in claim 5, wherein the work function material includes W, Co, Ti, Ni, Mo, TiN, TiSiN, WCN, TiWN, TaN, or combinations thereof, and the stressor element includes Sn, Pb, In, or combinations thereof.

7. The semiconductor device as claimed in claim 1, wherein a concentration of the stressor element in the work function layer is uniform.

8. The semiconductor device as claimed in claim 1, wherein the stressor element in the work function layer has concentrations gradually decreasing in a direction toward the top portion of the active region.

9. The semiconductor device as claimed in claim 1, wherein the stressor element in the work function layer has concentrations gradually decreasing in a direction away from the top portion of the active region.

10. The semiconductor device as claimed in claim 1, wherein the gate electrode is separated from the top portion of the active region by the gate dielectric layer, and the work function layer is in contact with the gate dielectric layer.

11. The semiconductor device as claimed in claim 1, wherein the gate electrode further includes a gate fill portion disposed on the work function layer opposite to the gate dielectric layer and formed with the seam.

12. The semiconductor device as claimed in claim 1, wherein the active region further includes a base portion which is spaced apart from the top portion of the active region, the gate structure being disposed around the top portion of the active region.

13. A method for manufacturing a semiconductor structure, comprising:
forming an active region over a substrate;
forming an isolation structure over the substrate and around a lower portion of the active region; and
forming a gate structure extending along surfaces of an upper portion of the active region and a top surface of the isolation structure, the gate structure having a curved top surface, the gate structure including a gate dielectric layer and a gate electrode over the gate dielectric layer, the gate electrode including a work function layer, the work function layer including a work function material and a stressor element doped in the work function material, the stressor element including a metal element that is different from a metal element in the work function material, the stressor element being present in an amount sufficient to permit the work function layer to apply a stress on the upper portion of the active region.

14. The method as claimed in claim 13, wherein the upper portion of the active region includes channel portions spaced apart from each other and surrounded by the work function layer, the work function layer including inner layer portions each disposed between two corresponding ones of the channel portions, and an outer layer portion connected to the inner layer portions, the stressor element being present in the outer layer portion and the inner layer portions.

15. The method as claimed in claim 13, wherein formation of the gate electrode includes
depositing the work function material to form work function portions respectively around the channel portions,
before two adjacent ones of the work function portions merge together at a location between two corresponding adjacent ones of the channel portions, forming a doping layer on the work function portions, the doping layer including the stressor element, and
performing a thermal treatment to drive the stressor element in the doping layer into the work function portions, and to form the work function layer.

16. The method as claimed in claim 13, wherein
the work function layer is formed by atomic layer deposition which includes
first deposition cycles, each of which includes forming a monolayer of the work function material on the gate dielectric layer, and
second deposition cycles, each of which includes forming a monolayer of the stressor element on the monolayer of the work function material, and
a total number of the second deposition cycles is less than a total number of the first deposition cycles, such that an average atomic concentration of the stressor element in the work function layer ranges from 0.5% to 10%.

17. The method as claimed in claim 13, wherein
when the work function material includes TiAl, TiAlN, TiAlC, TaAlSiC, TaAlC, TaAlSiC, or combinations thereof, the stressor element includes Cr, Mn, or a combination thereof, and
when the work function material includes W, Co, Ti, Ni, Mo, TiN, TiSiN, WCN, TiWN, TaN, or combinations thereof, the stressor element includes Sn, Pb, In, or combinations thereof.

18. A method for manufacturing a semiconductor structure, comprising:
forming a first channel region and a second channel region over a substrate and extending lengthwise along a direction;
forming an isolation structure over the substrate and between the first channel region and the second channel region, a top surface of the isolation structure is non-planar when viewed along the direction; and
forming a gate structure extending along surfaces of the first channel region, the second channel region and a top surface of the isolation structure, the gate structure including a gate dielectric layer and a gate electrode over the gate dielectric layer, the gate electrode including
a first work function layer disposed on the first channel region and separated from the first channel region by a first portion of the gate dielectric layer, the first work function layer including a first work function material and a first stressor element doped in the first work function material, so as to generate a tensile stress to be applied on the first channel region, the first stressor element including a metal element that is different from a metal element in the first work function material, and
a second work function layer disposed on the second channel region and separated from the second channel region by a second portion of the gate dielectric layer, the second work function layer including a second work function material and a second stressor element doped in the second work function material, so as to generate a compressive stress to be applied on the second channel region, the second stressor element including a metal element that is different from a metal element in the second work function material,
an atomic radius of the first stressor element being smaller than an atomic radius of the second stressor element.

19. The method as claimed in claim 18, wherein
the first work function material includes TiAl, TiAlN, TiAlC, TaAlSiC, TaAlC, TaAlSiC, or combinations thereof, the first stressor element including Cr, Mn, or a combination thereof, and
the second work function material includes W, Co, Ti, Ni, Mo, TiN, TiSiN, WCN, TiWN, TaN, or combinations thereof, and the second stressor element including Sn, Pb, In, or combinations thereof.

20. The method as claimed in claim 18, wherein the second work function layer further extends to be disposed on the first work function layer, the second work function layer having a stepped profile a location above the isolation structure.
